(19) United States
(12) Patent Application Publication
(10) Pub. No.: US 2011/0139272 A1
(43) Pub. Date: Jun. 16, 2011

(54) PROCESS-GAS SUPPLY AND PROCESSING SYSTEM

(75) Inventors: Kenji Matsumoto, Yamanashi-Ken (JP); Hitoshi Itoh, Yamanashi-Ken (JP)

(73) Assignee: TOKYO ELECTRON LIMITED, Tokyo (JP)

(21) Appl. No.: 12/675,222

(22) PCT Filed: Aug. 28, 2008
(86) PCT No.: PCT/JP2008/065430

§ 371 Date: Jun. 22, 2010

(30) Foreign Application Priority Data
Aug. 30, 2007 (JP) 2007-224759
Aug. 13, 2008 (JP) 2008-208782

(51) Int. Cl. F16K 15/00

(52) U.S. Cl. 137/511; 137/561 R

(57) ABSTRACT

A process-gas supply system 2 supplies a process gas diluted with a diluent gas to a gas using system 4. The process-gas supply system 2 includes a process gas tank 10, a diluent gas tank 12, a main gas duct 14 connecting the process gas tank 10 and the gas using system 4, and a diluent gas duct connecting the diluent gas tank 12 to the main gas duct. The respective main gas duct 14 and the diluent gas duct are provided with flow rate controllers FC1, FC2, and FC5. The diluent gas duct is connected to the main gas duct at a position on an immediately downstream side of one of a plurality of flow rate controllers other than the flow rate controller on the most downstream side. There is further provided a surplus-gas discharge duct 24 through which a surplus diluted process gas is discharged, the surplus-gas discharge duct 24 being connected to the main gas duct at a position on an immediately upstream side of one the flow rate controllers other than the flow rate controller on the most upstream side.

### FIELD OF THE INVENTION

The present invention relates to a processing apparatus configured to subject an object to be processed, such as a semiconductor wafer, to a predetermined process, such as an annealing process and a film deposition process, and a process-gas supply system used therefor. In particular, the present invention relates to a process-gas supply system and a processing apparatus capable of precisely diluting a process gas with a diluent gas, at a significantly high dilution ratio, such as a ratio ranging from a several ppb level to a several hundreds ppb level, and of supplying the diluted process gas.

### BACKGROUND ART

In general, when a semiconductor device is manufactured, a semiconductor wafer is generally subjected to various processes such as a film deposition process, an etching process, an annealing process, an oxidation and diffusion process, a modification process, and so on, repeatedly, so that a desired device is manufactured. Recently, in view of the demand for higher degree of integration and further miniaturization of a semiconductor device, a line width and a hole diameter have been more and more narrowed.

Under these circumstances, when the various aforementioned processes are performed, it is necessary to more strictly and more precisely control process conditions such as a process temperature and a process pressure. Simultaneously, a flow rate of a process gas should be more strictly and more precisely controlled. Particularly when a process gas of a slight amount is supplied, it is sometimes necessary to supply the process at a small flow rate, while precisely controlling such a small flow rate.

For example, as disclosed in JP2004-107747A, in recent years, there is sometimes used copper, which has a small electric resistance, as a wiring material and a material to be embedded into a recess such as a trench and a hole. When copper having a small electric resistance is used as an embedded material, the use of a self-forming barrier layer using an Mn film or a CuMn alloy film, in place of a conventional barrier film formed of a Ta film or a TaN film, has drawn attention (e.g., 3P2005-277390A). The Mn film and the CuMn alloy film are deposited by sputtering, and the Mn film and the CuMn alloy film themselves serve as seed films. Thus, a Cu plating layer can be directly formed above the Mn film and the CuMn alloy film. When the Mn film and the CuMn alloy film are annealed after Cu plating, a Mn component in the Mn film and the CuMn alloy film reacts with a lower SiO₂ film, which is an insulating film, in a self-aligning manner. Thus, on a boundary part between the SiO₂ layer and the plated Cu layer, there is formed a barrier film such as a MnSiₓO_{y} (x, y: given natural number) film or a manganese oxide MnₓO_{y} (x, y: given natural number) film. As a result, an advantageous effect can be obtained, i.e., the number of manufacturing steps can be reduced.

In order to improve reliability of a Cu wiring using a self-forming barrier film formed by the above-described Mn film or the CuMn alloy film, it is necessary to anneal, after a Cu layer has been formed, the Mn film or the CuMn alloy film in an O₂ atmosphere, so as to segregate surplus Mn in the Mn film or the CuMn alloy film above the Cu layer. At this time, in order to control a segregation degree of Mn to the Cu surface, an O₂ density (concentration) of the O₂ atmosphere should be set at a significantly low value ranging from a several ppb level to a several hundreds ppb level. In addition, the density is desired to be precisely controlled.

In another example, the Mn film or a Mn containing film can be formed by, e.g., a CVD (Chemical Vapor Deposition) method, with the use of an organic metal material containing Mn and a slight amount of moisture. The amount of the required moisture is very small. In order to form a reliable MnₓO_{y} barrier film, a flow rate of the moisture should be precisely controlled at a level from a several ppb to a several hundreds ppb.

For example, as disclosed in JP2006-521707T, a process gas is supplied at a small flow rate as described above. Namely, while the process gas is flown at a slight flow rate, the process gas is diluted with a large amount of diluent gas such as Ar and N₂, and the diluted process gas is supplied.

As described above, when a process gas, which is flown at a slight flow rate, is diluted with a diluent gas of a large amount, it is considerably difficult to precisely control a density of the process gas at the aforementioned significantly low density ranging from a several ppb level to a several hundreds ppb level, because of properties of a flow rate controller such as a mass flow controller.

Further, unless an enormous amount of diluent gas is flown, it is impossible to make a diluted process gas of a desired density. Furthermore, a part of the diluted process gas which is not required, i.e., a surplus of the diluted process gas should be discarded. Thus, the use of the diluent gas is inefficient, which increases a cost of the gas.

### DISCLOSURE OF THE INVENTION

Taking the above problems into consideration, the present invention has been made so as to efficiently solve the same. The object of the present invention is to provide a process-gas supply system and a processing apparatus, which are capable of precisely controlling a density of a process gas at a significantly low density (concentration) ranging from a several ppb level to a several hundreds ppb level. Another object of the present invention is to reduce a cost of the process gas by a reuse thereof.

A first process-gas supply system according to the present invention is a process-gas supply system configured to supply a process gas diluted with a diluent gas to a gas using system, the process-gas supply system comprising: a process gas tank configured to store the process gas; a diluent gas tank configured to store the diluent gas; a main gas duct connecting the process gas tank and the gas using system; a plurality of flow rate controllers disposed on the main gas duct; a diluent gas duct connecting the diluent gas tank to the main gas duct, the diluent gas duct being connected to the main gas duct at a position on an immediately downstream side of one of the flow rate controllers disposed on the main gas duct other than the flow rate controller on the most downstream side; a flow rate controller disposed on the diluent gas duct; and a surplus-gas discharge duct through which a surplus diluted process gas is discharged from the main gas duct, the surplus-gas discharge duct being connected to the main gas duct at a position on an immediately upstream side of one of the flow rate controllers disposed on the main gas duct other than the flow rate controller on the most upstream side.

Due to the first process-gas supply system according to the present invention, by diluting the process gas, which has flown, with a flow rate thereof being controlled, from the process gas tank through the main gas duct, with the diluent gas, which has flown, with a flow rate thereof being controlled, through the diluent gas duct, a diluted process gas can be generated. The diluted process gas is supplied with a flow rate thereof being controlled. At this time, a surplus part of the diluted process gas can be discharged. As a result, a density of the process gas can be precisely controlled even when the density is within a significantly low density range from a several ppb level to a several hundreds ppb level.

In the first process-gas supply system according to the present invention, a pure process gas or a process gas diluted with a diluent gas to a predetermined density may be accommodated in the process gas tank. In particular, when the process gas diluted with the diluent gas to a predetermined density is accommodated in the process gas tank, the density of the process gas can be precisely controlled even when the density is within a further lower density range.

In the first process-gas supply system according to the present invention, the process gas may be an O₂ gas.

A second process-gas supply system according to the present invention is a process-gas supply system configured to supply a process gas diluted with a diluent gas to a gas using system, the process-gas supply system comprising: a liquid material tank configured to store a liquid material of the process gas; a diluent gas tank configured to store the diluent gas; a main gas duct connecting the liquid material tank and the gas using system; a flow rate controller disposed on the main gas duct; and a diluent gas duct connecting the diluent gas tank to the main gas duct, the diluent gas duct being connected to the main gas duct at a position on a downstream side of the flow rate controller disposed on the main gas duct.

Due to the second process-gas supply system according to the present invention, a liquid material is used as a material of the process gas. By diluting the process gas, which has flown, with a flow rate thereof being controlled, from the process gas tank storing the liquid material, with the diluent gas, which has flown with a flow rate thereof being controlled, through the diluent gas duct, a diluted process gas can be generated. The diluted process gas is supplied with a flow rate thereof being controlled. As a result, a density of the process gas can be precisely controlled even when the density is within a significantly low density range from a several ppm level to a several hundreds ppm level.

In the second process-gas supply system according to the present invention, the liquid material tank may be configured such that a process gas, which is generated by evaporating the liquid material in the liquid material tank, outflows to the main gas duct.

The second process-gas supply system according to the present invention may further comprises: a plurality of flow rate controllers disposed on the main gas duct; and a surplus-gas discharge duct through which a surplus diluted process gas is discharged from the main gas duct, the surplus-gas discharge duct being connected to the main gas duct at a position on an immediately upstream side of one of the flow rate controllers disposed on the main gas duct other than the flow rate controller on the most upstream side, wherein the diluent gas duct is connected to the main gas duct at a position on an immediately downstream side of one of the flow rate controllers disposed on the main gas duct other than the flow rate controller on the most downstream side.

The second process-gas supply system according to the present invention may further comprises a pressure regulating valve mechanism disposed on the main gas duct at a position on the immediately downstream side of the liquid material tank.

In the second process-gas supply system according to the present invention, the process gas may be a steam (H₂O).

A third process-gas supply system according to the present invention is a process-gas supply system configured to supply a process gas diluted with a diluent gas to a gas using system, the process-gas supply system comprising: a liquid material tank configured to store a liquid material of the process gas; a diluent gas tank configured to store the diluent gas; a bubbling mechanism configured to evaporate the liquid material so as to generate the process gas, by introducing a rare gas to the liquid material stored in the liquid material tank, with a flow rate of the rare gas being controlled by a flow rate controller; a main gas duct connecting the liquid material tank and the gas using system; a diluent gas duct connecting the diluent gas tank to the main gas duct; and a flow rate controller disposed on the diluent gas duct.

Due to the third process-gas supply system according to the present invention, a liquid material is used as a material of the process gas. By introducing the diluent gas, with a flow rate thereof being controlled, into the liquid material tank storing the liquid material, namely, by bubbling the liquid material as the material of the process gas by means of the diluent gas, a process gas is generated. In addition, by diluting the process gas with the diluent gas, which has flown, with a flow rate thereof being controlled through the diluent gas duct, a diluted process gas can be generated. Thus, a density of the process gas can be precisely controlled even when the density is within a significantly low density range from a several ppm level to a several hundreds ppm level.

The third process-gas supply system may further comprises: a flow rate controller disposed on the main gas duct; and a surplus-gas discharge duct through which a surplus diluted process gas is discharged from the main gas duct, the surplus-gas discharge duct being connected to the main gas duct at a position on an immediately upstream side of the flow rate controller disposed on the main gas duct.

The third process-gas supply system may further comprises: a plurality of flow rate controllers disposed on the main gas duct; and a surplus-gas discharge duct through which a surplus diluted process gas is discharged from the main gas duct, the surplus-gas discharge duct being connected to the main gas duct at a position on an immediately upstream side of one of the flow rate controllers disposed on the main gas duct other than the flow rate controller on the most upstream side; wherein the diluent gas duct is connected to the main gas duct at a position on an immediately downstream side of one of the flow rate controllers disposed on the main gas duct other than the flow rate controller on the most downstream side. In such a process-gas supply system, the diluent gas duct and the surplus-gas discharge duct may be disposed in a stepwise manner, so that dilution of the process gas can be repeatedly performed in a stepwise manner, by repeating dilution of the process gas and discharge of the surplus gas. Thus, a density of the process gas can be precisely controlled even when the density is within a further lower density range. Owing to the stepwise structure, a total amount of the diluent gas to be used can be decreased.

The third process-gas supply system according to the present invention may further comprises a pressure regulating valve mechanism disposed on the main gas duct at a position on an immediately downstream side of the liquid material tank.

In the third process-gas supply system according to the present invention, the process gas may be a steam (H₂O).

Any one of the first to third process-gas supply systems according to the present invention may further comprises: a density measuring instrument configured to measure a density of the process gas, the density measuring instrument being disposed on the main gas duct at a position immediately before the gas using system, or on the gas using system; and a feedback control device configured to feedback-control a flow rate controller based on a value detected by the density measuring instrument. In such a process-gas supply system, the flow rate controller to be feedback-controlled by the feedback control device may be the flow rate controller disposed on the main gas duct. Alternatively, in such a process-gas supply system, the flow rate controller to be feedback-controlled by the feedback control device may be the flow rate controller disposed on the diluent gas duct. Due to such a process-gas supply system, since a density of the process gas to be introduced to the gas using system can be detected, a feedback control can be performed. Thus, a density of the process gas can be precisely, stably, controlled even when the density is within a significantly low density range.

A fourth process-gas supply system according to the present invention is a process-gas supply system configured to supply a process gas diluted with a diluent gas to a gas using system, the process-gas supply system comprising: a process-gas forming part configured to form the process gas; a diluent gas tank configured to store the diluent gas; a main gas duct connecting the process-gas forming part and the gas using system; a flow rate controller disposed on the main gas duct; a diluent gas duct connecting the diluent gas tank to the main gas duct, the diluent gas duct being connected to the main gas duct at a position on an upstream side of the flow rate controller disposed on the main gas duct; a flow rate controller disposed on the diluent gas duct; and a surplus-gas discharge duct through which a surplus diluted process gas is discharged from the main gas duct, the surplus-gas discharge duct being connected to the main gas duct at a position on the immediately upstream side of the flow rate controller disposed on the main gas duct.

Due to the fourth process-gas supply system according to the present invention, by diluting the process gas, which has flown, with a flow rate thereof being controlled, from the process gas tank through the main gas duct, with the diluent gas, which has flown, with a flow rate thereof being controlled, through the diluent gas duct, a diluted process gas can be generated. The diluted process gas is supplied with a flow rate thereof being controlled. At this time, a surplus part of the diluted process gas can be discharged. As a result, a density of the process gas can be precisely controlled even when the density is within a significantly low density range from a several ppb level to a several hundreds ppb level.

In the fourth process-gas supply system according to the present invention, the process-gas forming part may include: a material-gas supply system configured to supply a plurality of material gases for forming the process gas, with flow rates of the material gases being independently controlled; and a reaction part configured to react the plurality of material gases from the material-gas supply system so as to form the process gas. In such a process-gas supply system, a purity of the process gas formed by the process-gas forming part can be maintained high, and a density thereof can be precisely controlled.

In the fourth process-gas supply system according to the present invention, the plurality of material gases are an H₂ gas and an O₂ gas, and the process gas is a steam (H₂O).

The fourth process-gas supply system according to the present invention may further comprises: a density measuring instrument configured to measure a density of the process gas, the density measuring instrument being disposed on the main gas duct at a position immediately before the gas using system, or on the gas using system; and a feedback control device configured to feedback-control a flow rate controller based on a value detected by the density measuring instrument. In such a process-gas supply system, the flow rate controller to be feedback-controlled by the feedback control device may be the flow rate controller disposed on the main gas duct, or a flow rate controller disposed on the process-gas forming part. Alternatively, in such a process-gas supply system, the flow rate controller to be feedback-controlled by the feedback control device may be the flow rate controller disposed on the diluent gas duct.

Any one of the first to fourth process-gas supply systems according to the present invention may further comprises a reusable gas duct connecting the surplus-gas discharge duct and the diluent gas duct, wherein the reusable gas duct is configured such that all the discharged surplus gas or a part thereof in the surplus-gas discharge duct can be reused as the diluent gas. Due to such a process-gas supply system, all the discharged surplus gas, or a part of the discharged surplus gas can be reused, whereby a cost of the gas can be decreased, and an operation cost can be reduced.

In such a process-gas supply system, the reusable gas duct may be provided with a process-gas removal filter configured to absorb the process gas from the diluted process gas containing the diluent gas and the process gas, and the process-gas removal filter may be configured to remove the process gas from the diluted process gas flowing through the reusable gas duct, and to allow the diluent gas to pass therethrough.

Any one of the first to fourth process-gas supply systems according to the present invention may further comprises a reusable gas duct connecting the surplus-gas discharge duct and an exhaust system disposed on the gas using system, wherein the reusable gas duct is configured such that all the discharged surplus gas or a part thereof in the surplus-gas discharged duct can be reused as a purge gas for a vacuum pump of the exhaust system.

In such a process-gas supply system, the reusable gas duct may be provided with a process-gas removal filter configured to absorb the process gas from the diluted process gas containing the diluent gas and the process gas, and the process-gas removal filter may be configured to remove the process gas from the diluted process gas flowing through the reusable gas duct, and to allow the diluent gas to pass therethrough.

Any one of the first to fourth process-gas supply systems according to the present invention may further comprises a discarded-gas discharge duct connected to the main gas duct at a position on the downstream side of the flow rate controller on the most downstream side, wherein the discarded-gas discharge duct is configured such that the process gas flowing therethrough bypasses the gas using system and is discarded.

In any one of the first fourth process-gas supply systems according to the present invention, the surplus-gas discharge duct may be provided with a check valve that is opened when a pressure of the process gas reaches or exceeds a predetermined pressure. In such a process-gas supply system, the surplus-gas discharge duct may be provided with a needle valve at a position on the upstream side of the check valve.

Any one of the first to fourth process-gas supply systems according to the present invention may further comprises: a pressure gauge disposed on the main gas duct, the pressure gauge being configured to measure a gas pressure in the main gas duct; a pressure regulating valve disposed on the surplus-gas discharge duct; and a valve control device configured to control a valve opening degree of the pressure regulating valve based on a value measured by the pressure gauge.

In any one of the first to fourth process-gas supply systems according to the present invention, a part of the main gas duct, which part is located between a connection position to which the surplus-gas discharge duct is connected and a connection position to which the diluent gas duct is connected on the downstream side of the former connection point to which the surplus-gas discharge duct is connected, may have a cross section smaller than those of other parts of the main gas duct, the other parts being located adjacent to the part on the upstream side and the downstream side.

Any one of the first to fourth process-gas supply systems according to the present invention may further comprises: a zirconia-type density measuring instrument disposed on the main gas duct, the zirconia-type measuring instrument being configured to measure an oxygen density of a gas in the main gas duct; and a feedback control part configured to feedback-control a flow rate controller based on a value detected by the zirconia-type density measuring instrument. Such a process-gas supply system may further comprises a measuring-instrument bypass pipe provided with an opening and closing valve, the measuring-instrument bypass pipe being disposed on the main gas duct, wherein the measuring-instrument bypass pipe is configured such that the process gas flowing therethrough bypasses the zirconia-type measuring instrument.

In any one of the first to fourth process-gas supply systems according to the present invention, the gas using system may be a film deposition apparatus configured to deposit a film on a surface of an object to be processed, or an annealing apparatus configured to anneal an object to be processed on which a film has been formed. In such a process-gas supply system, the film may be any one of a CuMn film, a high dielectric constant film, an Mn film, and a film containing Mn.

Any one of the first to fourth process-gas supply system according to the present invention may further comprises a mixer disposed on the main gas duct at a position to which the diluent gas duct is connected.

In any one of the first to fourth process-gas supply systems according to the present invention, the diluent gas may be formed of one or more gases selected from the group consisting of an N₂ gas and a rare gas.

A processing system according to the present invention is a processing system configured to subject an object to be processed to a predetermined process, the processing apparatus comprising: a processing container capable of accommodating one or more objects to be processed; a gas introduction member configured to introduce a gas into the processing container; and the process-gas supply system according to claim 1, connected to the gas introduction member for supplying a process gas diluted with a diluent gas into the processing container.

The processing system according to the present invention may further comprises an exhaust system configured to discharge an atmosphere in the processing container, wherein the exhaust system includes: a main exhaust duct provided with an opening and closing valve and a vacuum pump; and a bypass exhaust duct provided with an opening and closing valve, for atmospheric pressure process, the bypass exhaust duct being connected to the main exhaust duct such that the bypass exhaust duct bypasses the vacuum pump.

Due to the process-gas supply system and the processing apparatus according to the present invention, a density of the process gas can be precisely controlled even when the density is within a significantly low density range from a several ppm level to a several hundreds ppm level, or still even when the density is within a significantly low density range from a several ppb level to a several hundreds ppb level. Moreover, since the process gas can be reused, a cost of the gas can be decreased, and an operation cost can be reduced.

### BRIEF DESCRIPTION OF THE DRAWINGS

FIG. 1 is a structural view showing a first embodiment of a process-gas supply system according to the present invention, which is connected to a processing apparatus.

FIG. 2A is a view showing an example of a connection part between a main gas duct and a diluent gas duct.

FIG. 2B is a view showing another example of the connection part between the main gas duct and the diluent gas duct.

FIG. 2C is a view showing a still another example of the connection part between the main gas duct and the diluent gas duct.

FIG. 2D is a view showing a still another example of the connection part between the main gas duct and the diluent gas duct.

FIG. 2E is a view showing a still another example of the connection part between the main gas duct and the diluent gas duct.

FIG. 2F is a view showing a still another example of the connection part between the main gas duct and the diluent gas duct.

FIG. 3 is a structural view showing a second embodiment of the process-gas supply system according to the present invention, which is connected to the processing apparatus.

FIG. 4 is a structural view showing a third embodiment of the process-gas supply system according to the present invention, which is connected to the processing apparatus.

FIG. 5 is a structural view showing a fourth embodiment of the process-gas supply system according to the present invention, which is connected to the processing apparatus.

FIG. 6 is a structural view showing a fifth embodiment of the process-gas supply system according to the present invention, which is connected to the processing apparatus.

FIG. 7 is a structural view showing a sixth embodiment of the process-gas supply system according to the present invention, which is connected to the processing apparatus.

FIG. 8 is a structural view showing a seventh embodiment of the process-gas supply system according to the present invention, which is connected to the processing apparatus.

FIG. 9 is a structural view showing an eighth embodiment of the process-gas supply system according to the present invention, which is connected to the processing apparatus.

FIG. 10 is a structural view showing a ninth embodiment of the process-gas supply system according to the present invention, which is connected to the processing apparatus.

FIG. 11 is a structural view showing a tenth embodiment of the process-gas supply system according to the present invention, which is connected to the processing apparatus.

FIG. 12 is a partial structural view showing an eleventh embodiment of the process-gas supply system according to the present invention, which is connected to the processing apparatus.

FIG. 13 is a partial structural view showing a twelfth embodiment of the process-gas supply system according to the present invention, which is connected to the processing apparatus.

FIG. 14A is a schematic structural view showing an example of the processing apparatus which is a gas using system.

FIG. 14B is a schematic structural view showing another example of the processing apparatus which is a gas using system.

### MODE FOR CARRYING OUT THE INVENTION

Preferred embodiments of a process-gas supply system and a processing apparatus according to the present invention will be described herebelow, with reference to the accompanying drawings. In the respective embodiments described below, given as an example of a processing apparatus is a gas using system, which is configured to subject an object to be processed such as a semiconductor wafer, to various processes such as a film deposition process and an annealing process. In the following examples, an O₂ gas or a steam (H₂O) is used as a process gas, and an Ar gas which is a rare gas (a noble gas) is used as a diluent gas.

### First Embodiment

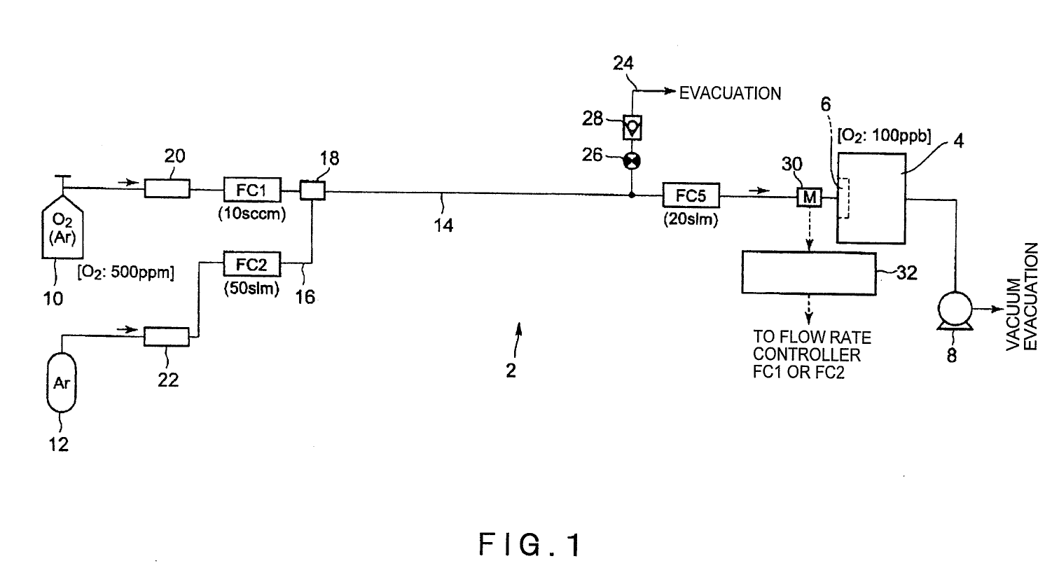

FIG. 1 is a structural view showing a first embodiment of a process-gas supply system according to the present invention, which is connected to a processing apparatus. As shown in FIG. 1, a processing apparatus 4 is used as a gas using system, as described above. A process-gas supply system 2 is connected to a gas introduction member 6 of the processing apparatus 4, in order to subject an object to be processed such as a semiconductor wafer, to various processes such as a film deposition process and an annealing process. An inside of the processing apparatus 4 is vacuumized by a vacuum pump 8 constituting an exhaust system (vacuum system), and thus is filled with a reduced pressure atmosphere.

The process-gas supply system 2 includes a process gas tank 10 that stores a process gas used in the processing apparatus 4, and a diluent gas tank 12 that stores a diluent gas for diluting the process gas. In this case, the process gas tank 10 and the diluent gas tank 12 may respectively store materials of the gases either in a liquid state or in a gaseous state.

As each of the tanks 10 and 12, there can be used a tank equipment as a permanent factory equipment provided in a semiconductor manufacturing factory in which the processing apparatus 4 is installed, or a movable tank equipment capable of being transferred. This point holds true with the following other embodiments.

Particularly in the first embodiment, a pure diluent gas having a density of essentially 100% is stored in the diluent gas tank 12, and a process gas diluted with the diluent gas to have a predetermined density is stored in the process gas tank 10. As described above, an Ar gas is used as the diluent gas, and an O₂ gas is used as the process gas. Thus, the process gas tank 10 is filled with an O₂ gas diluted with an Ar gas. A content of O₂ stored in the process gas tank 10 is set at about 500 ppm, for example. A diluted process gas having an O₂ density of such a degree can be relatively easily manufactured by a gas manufacturing company with a high precision. In this example, a movable-type tank equipment is used as the process gas tank 10, and a fixed-type tank equipment of a factory equipment is used as the diluent gas tank 12.

A main gas duct 14 is disposed so as to connect the process gas tank 10 and the gas introduction member 6 of the processing apparatus 4. In the illustrated example, the main gas duct 14 is provided with a plurality of flow rate controllers, e.g., two flow rate controllers FC1 and FC5, which are disposed in this order from an upstream side to a downstream side. In addition, a diluent gas duct 16 is extended from the diluent gas tank 12. A distal end of the diluent gas duct 16 is connected to the main gas duct 14.

To be specific, the number of the diluent gas duct 16 in this example is one. The distal end of the diluent gas duct 16 is connected to the main gas duct 14 at a position on the immediately downstream side of one of the flow rate controllers other than the flow rate controller FC5 on the most downstream side, i.e., at a position on the immediately downstream side of the flow rate controller FC1 on the most upstream side. Thus, a diluted process gas flowing from the process gas tank 10 can be further diluted with a diluent gas which is newly introduced from the diluent gas duct 16.

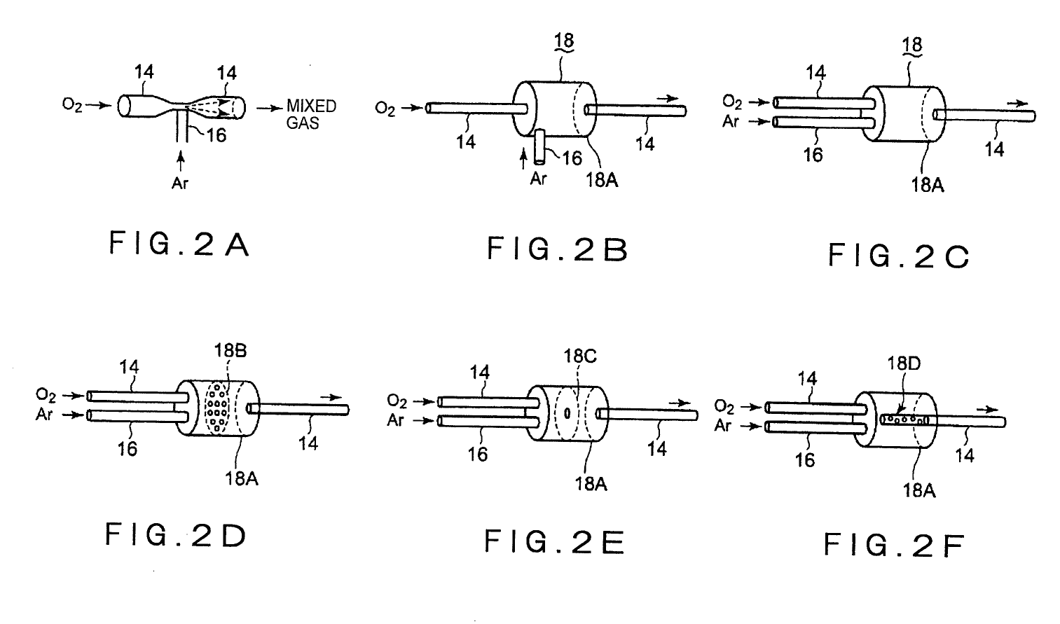

A connection part between the main gas duct 14 and the diluent gas duct 16 can be structured as shown in FIG. 2. For example, as shown in FIG. 2A, a diameter of a part of the main gas duct 14 may be reduced, and the diluent gas duct 16 may be joined to the reduced-diameter part. Due to such a structure, a venture effect can be expected. More preferably, as shown in FIGS. 2B to 2F, a mixer 18 for promoting mixture of the gases may be provided. As shown in FIGS. 2B and 2C, the mixer 18 includes a container body 18A having a certain volume. In the mixer 18, a process gas flowing downstream through the main gas duct 14 is introduced from one end of the container body 18A, and the process gas outflows downstream from the other end of the container body 18A. In the container body 18A, the process gas is diluted with the diluent gas having flown downstream through the diluent gas duct 16.

In this case, as shown in FIG. 2B, the end of the diluent gas duct 16 may be connected to a side surface of the container body 18A. Alternatively, as shown in FIG. 2C, the end of the diluent gas duct 16 may be connected to an end surface of the container body 18 to which the main gas duct 14 extending from the upstream side is connected. In the container body 18A, balls made of a SUS (stainless steel) or ceramic may be contained, or various filter media may be provided. Further, as shown in FIG. 2D, an apertured baffle plate 18B having a plurality of openings may be disposed in the container body 18A. As shown in FIG. 2E, an orifice plate 18C having an orifice may be disposed in the container body 18A. Alternatively, as shown in FIG. 2F, a part of a pipe of the main gas duct 14 may be prolonged into the container body 18A, and a plurality of holes may be formed in the part of the pipe extending in the container body 18A. Namely, a part of the pipe of the main gas duct 14 may be formed as an apertured pipe 18D. The aforementioned matters relating to the connection part between the diluent gas duct 16 and the main gas duct 14 are similarly applied to all the embodiments described below.

The diluent gas duct 16 is provided with a flow rate controller FC2. Thus, a diluent gas can be flown, with a flow rate thereof being controlled. As the flow rate controllers FC1, FC2, and FC5, there may be used mass flow controllers, throttle flowmeters, and pressure-controlled flow controllers using sonic nozzles. This point holds true with the embodiments described below.

The main gas duct 14 is provided with an inline gas refiner 20 at a position on the immediately downstream side of the process gas tank 10, and the diluent gas duct 16 is provided with an inline gas refiner 22 at a position on the immediately downstream side of the diluent gas tank 12. The inline gas refiners 20 and 22 are configured to remove impurities such as a moisture in the gases flowing through the respective ducts 14 and 16. In addition, connected to the main gas duct 14 is a surplus-gas discharge duct 24 at a position on the immediately upstream side of one flow rate controller, which is other than the flow rate controller FC1 on the most upstream side, of the plurality of, i.e., two in this example, flow rate controllers FC1 and FC5 of the main gas duct 14. Namely, in this example, the surplus-gas discharge duct 24 is connected to the main gas duct 14 at a position on the immediately upstream side of the flow rate controller FC5 and on the downstream side of the mixer 18. The surplus-gas discharge duct 24 is provided with an opening and closing valve 26 and a check valve 28 for discharging a surplus gas. Thus, when a pressure in the main gas duct 14 reaches or exceeds a predetermined pressure, the check valve 28 is opened so that a surplus diluted process gas can be discharged outside the system. The downstream side of the surplus-gas discharge duct 24 may be connected to, e.g., the upstream side of the vacuum pump 8 included in the exhaust system of the processing apparatus 4, or a pressure-reduced exhaust duct on the downstream side of the vacuum pump 8.

In addition, at a position immediately before the processing apparatus 4, the main gas duct 14 is provided with a density measuring instrument 30 that measures a density of the process gas flowing through the main gas duct 14. In this example, a density of O₂ as the process gas can be measured. As the density measuring instrument 30, there may be used a Q-mass (quadrupole mass spectrometer) having a differential pumping function. Alternatively, as the density measuring instrument 30, there may be used an analyzer of a limiting current type (zirconia type), a magnetic flow rate ratio type, or a diaphragm galvanic cell type, and a Fourier transform infrared spectrometer (FT-IR). A value detected by the density measuring instrument 30 is inputted to a feedback control part 32 formed of, e.g., a computer. The upstream-side flow rate controller FC1 or FC2 excluding the flow rate controller FC5 is controlled by the feedback control part 32, whereby a predetermined process gas density, i.e., a predetermined O₂ density can be maintained. The density measuring instrument 30 may be disposed not in the main gas duct 14 but in the processing apparatus 4.

Next, an operation of the process-gas supply system 2 as structured above is described. Firstly, upon operation of the processing apparatus 4, the vacuum pump 8 disposed on the processing apparatus 4 is continuously driven, so that the inside of the processing apparatus 4 is exhausted. As a result, when the processing apparatus 4 is operated, the inside of the processing apparatus 4 is maintained at a predetermined reduced-pressure atmosphere of, e.g., 10⁻⁷ Pa.

A diluted process gas containing an O₂ gas as a process gas, which has been previously diluted with an Ar gas as a diluent gas to about 500 ppm, is supplied from the process gas tank 10 so as to flow downstream through the main gas duct 14. A flow rate of the diluted process gas is controlled by the flow rate controller FC1 at about 10 sccm, for example. Impurities such as a moisture contained in the diluted process gas flowing downstream through the main gas duct 14 are removed by the inline gas refiner 20. A control precision of a flow rate controller is generally about 1% of a full scale which is a range wherein a flow rate can be controlled. Thus, by changing the full scale according to need, various densities and flow rates can be achieved. Then, as described above, the diluted process gas from which the impurities such as a moisture have been removed passes through the flow rate controller FC1, and thereafter flows into the mixer 18.

On the other hand, an Ar gas as a diluent gas is supplied from the diluent gas tank 12. The Ar gas as a diluent gas flows downstream through the diluent gas duct 16, with a flow rate of the Ar gas being controlled at about 50 slm. Impurities such as a moisture contained in the diluent gas are removed by the inline gas refiner 22. The Ar gas from which the impurities such as a moisture have been removed passes through the flow rate controller FC2, and thereafter flows into the mixer 18. In the mixer 18, the diluted process gas having flown through the main gas duct 14 is uniformly mixed with the Ar gas having flown through the diluent gas duct 16. Thus, after the diluted process gas has been further diluted in the mixer 18, the diluted process gas outflows from the mixer 18 to the main gas duct 14 on the downstream side. As a result, the density of O₂ in the diluted process gas becomes, for example, about 100 ppb.

In this manner, the diluted process gas whose O₂ density has been diluted to about 100 ppb flows further downstream. A flow rate of the diluted process gas which has been further diluted is controlled by the flow rate controller FC5 at about 20 slm, for example. Then, the diluted process gas whose flow rate has been controlled further flows downstream through the main gas duct 14, so as to be introduced into the processing apparatus 4. The diluted process gas introduced into the processing apparatus 4 is used for a predetermined process such as an annealing process. Thus, the process gas whose O₂ density has been diluted with Ar to a value as low as about 100 ppb is used in the processing apparatus 4. When another process gas other than O₂ is required in the gas using system, it goes without saying that the required gas of another type is introduced into the processing apparatus from a gas supply system, not shown.

At this time, a surplus diluted process gas stagnates in a part of the main gas duct 14 between the mixer 18 and the flow rate controller FC5. When a pressure of this part reaches or exceeds a predetermined value, the check valve 28 disposed on the surplus-gas discharge duct 24 is opened, so that the surplus diluted process gas is discharged outside the system through the surplus-gas discharge duct 24. In addition, by means of the density measuring instrument 30 disposed on the main gas duct 14 at the position immediately before the processing apparatus 4, a density of the process gas in the diluted process gas, i.e., an O₂ gas density is measured and detected. A value detected by the density measuring instrument 30 is inputted to the feedback control part 32. The feedback control part 32 controls the flow rate controller FC1 or the flow rate controller FC2, such that the O₂ density of the diluted process gas is maintained at a set value.

When the O₂ density is regulated by feedback-controlling the flow rate controller FC2 of the diluent gas duct 16 having a large flow rate, a flow rate precision can be improved, although a response speed is decelerated. On the contrary, when the O₂ density is regulated by feedback-controlling the flow rate controller FC1 disposed on the main gas duct 14, the flow rate of the process gas, which is considerably smaller than the flow rate of the diluent gas flowing through the diluent gas duct 16, is controlled. Thus, a response speed can be accelerated, although a flow rate precision is somewhat degraded. In terms of another point of view, by suitably selecting the full scale (FS) of the flow rate controller, an optimum operation can be selected. That is to say, when priority is given to a precision of the flow rate control, it is effective to dispose a flow rate controller having an FS which is approximate to a flow rate (nominal flow rate) at which a gas is actually flown through the flow rate controller (for example, when the nominal flow rate is 10 sccm, the FS is 20 sccm). On the other hand, when priority is given to a speed of the flow rate control, it is effective to dispose a flow rate controller having an FS which is greatly larger than a flow rate at which a gas is actually flown through the flow rate controller (for example, when the nominal flow rate is 10 sccm, the FS is 100 sccm).

In this manner, by diluting the process gas, which has flown, with its flow rate being controlled, from the process gas tank 10 through the main gas duct 14, with the diluent gas, which has flown, with its flow rate being controlled, through the diluent gas duct 16, the density of the diluted process gas can be controlled. In addition, the flow rate of the diluted process gas is controlled, as well as the surplus diluted process gas is discharged outside the system. Therefore, the density of the process gas, such as the O₂ density, can be precisely controlled within a significantly low density range from a several ppb level to a several hundreds ppb level.

In addition, since the process gas, which has been previously diluted with the diluent gas to a predetermined density, is accommodated in the process gas tank 10, the density of the process gas can be precisely controlled even when the density is within a further lower density range. In addition, the density of the process gas to be introduced to the processing apparatus 4 as the gas using system is detected for a feedback control, the density of the process gas can be precisely, stably controlled within a significantly low density range.

### Second Embodiment

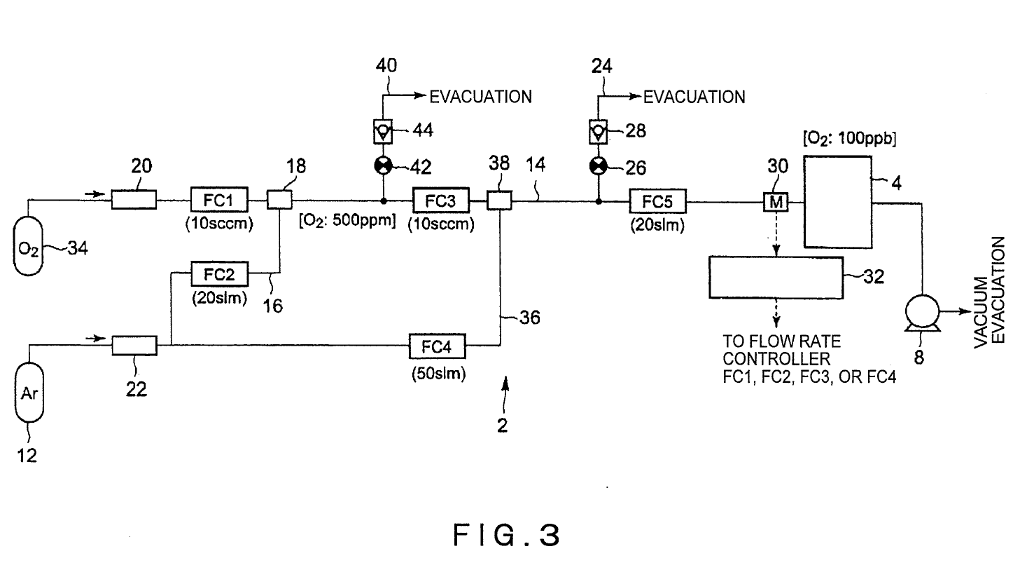

Next, a second embodiment of the process-gas supply system according to the present invention is described. FIG. 3 is a structural view showing the second embodiment of the process-gas supply system according to the present invention, which is connected to the processing apparatus 4. In FIG. 3, the same components as the components shown in FIGS. 1 and 2 are shown by the same reference numbers, and a detailed description thereof is omitted.

In the above first embodiment, there has been described the example in which the process gas tank 10 is filled with the gas which has been previously, precisely diluted with the diluent gas to a predetermined O₂ density of 500 ppm, for example. On the other hand, in the second embodiment of the process-gas supply system, there is used, in place of the process gas tank 10 in the first embodiment, a process gas tank 34 which is filled with a pure O₂ gas as a process gas. The pure process gas is diluted with a diluent gas in a stepwise manner, e.g., in two steps in this embodiment.

To be specific, a new diluent gas duct 36 is branched from the diluent gas duct 16. The new diluent gas duct 36 is provided with a flow rate controller FC4 which is different from the flow rate controllers FC1, FC2, and FC5 as described above. A distal end of the diluent gas duct 36 is connected to the main gas duct 14 via a new mixer 38 which is different from the mixer 18 as described above. The connection position of the diluent gas duct 36 to the main gas duct 14 is a position between a position at which the mixer 18, which is described in the above first embodiment, is connected to the main gas duct 14, and a position at which the surplus-gas discharge duct 24 is connected to the main gas duct 14.

At a position on the immediately upstream side of the mixer 38, the main gas duct 14 is provided with another flow rate controller FC3. In addition, at a position on the immediately upstream side of the flow rate controller FC3 and on the downstream side of the mixer 18, connected to the main gas duct 14 is a new surplus-gas discharge duct 40. The surplus-gas discharge duct 40 is provided with an opening and closing valve 42 and a check valve 44 for discharging a surplus gas. When a pressure of a part in the main gas duct 14, which is located near to the position to which the surplus-gas discharge duct 40 is connected, reaches or exceeds a predetermined value, the check valve 44 is opened so that a surplus diluted process gas is discharged outside the system. In this case, pressure values at which the check vales 28 and 44 are opened are set such that the pressure in the main gas duct 14 becomes larger toward the upstream side of the main gas duct 14. In this case, a feedback of the feedback control part 32 is fed to any one of the flow rate controllers FC1 to FC4.

Next, an operation of the above second embodiment is described. In this embodiment, a set value of the flow rate controller FC1 is 10 sccm, a set value of the flow rate controller FC2 is 20 slm, a set value of the flow rate controller FC3 is 10 sccm, a set value of the flow rate controller FC4 is 50 slm, and a set value of the flow rate controller FC5 is 20 slm. Firstly, a pure O₂ gas flows from the process gas tank 34 toward the main gas duct 14. A gas flow rate of the pure O₂ gas is controlled to 10 sccm by the flow rate controller FC1 at the first step. The pure O₂ gas is uniformly mixed by the mixer 18 at the first step with an Ar gas having flown through the diluent gas duct 16, so that the pure O₂ is diluted with the Ar gas. A flow rate of the Ar gas at this time is controlled to 20 slm by the flow rate controller FC2. Thus, an O₂ density of the diluted process gas, which is diluted in the mixer 18, becomes about 500 ppm.

The diluted process gas outflowing from the mixer 18 flows into the mixer 38 at the second step, with a flow rate of the diluted process gas being controlled to 10 sccm by the flow rate controller FC3 at the second step. In the mixer 38, the diluted process gas having an O₂ density of 500 ppm is uniformly mixed with an Ar gas having flown through the diluent gas duct 36, so that the diluted process gas is further diluted with the Ar gas. A flow rate of the Ar gas flowing into the mixer 38 at the second step is controlled to 50 slm by the flow rate controller FC4. Thus, the O₂ density of the diluted process gas diluted in the mixer 38 becomes 100 ppb (the O₂ density is the same as that of the first embodiment). After that, the diluted process gas, which has been diluted in two steps, is introduced into the processing apparatus 4, with a flow rate of the diluted process gas being controlled to 20 slm by the flow rate controller FC5.

Also in this embodiment, the surplus diluted process gas, which stagnates on the upstream sides of the respective flow rate controllers FC3 and FC5, is discharged outside the system through the respective surplus-gas discharge ducts 40 and 24. In this second embodiment, the flow rate set values of the respective flow rate controllers FC3, FC4, and FC5 correspond to the flow rate set values of the respective flow rate controllers FC1, FC2, and FC5 in the first embodiment.

In the second embodiment, when the O₂ density is regulated by feedback-controlling the flow rate controller FC2 or the flow rate controller FC4 of the diluent gas duct 16 or 36 through which a gas passes at a large flow rate, a flow rate precision can be improved, although a response speed is decelerated. On the contrary, when the O₂ density is regulated by feedback-controlling the flow rate controller FC1 or the flow rate controller FC3 which are disposed on the main gas duct 14, the flow rate of the process gas, which is considerably smaller than the flow rate of the diluent gas flowing through the diluent gas duct 16, is controlled. Thus, a response speed can be accelerated, although a flow rate precision is somewhat degraded. Also in this embodiment, the same operation and the same effect as those of the first embodiment can be realized.

### Third Embodiment

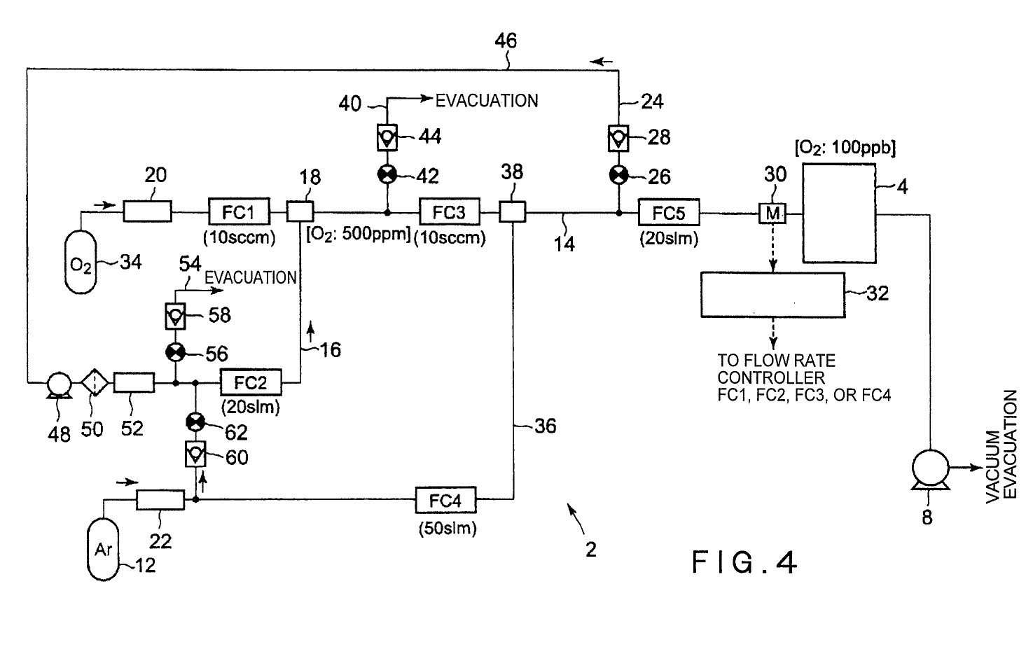

Next, a third embodiment of the process-gas supply system according to the present invention is described. FIG. 4 is a structural view showing the third embodiment of the process-gas supply system according to the present invention, which is connected to the processing apparatus 4. In FIG. 4, the same components as the components shown in FIGS. 1 to 3 are shown by the same reference numbers, and a detailed description thereof is omitted.

In the above second embodiment, all the surplus gas discharged from the surplus-gas discharge ducts 24 and 40 is discarded. Meanwhile, in the third embodiment, a part of the surplus gas discharged outside the system is reused. To be specific, the surplus gas having a lower O₂ density, i.e., the surplus gas discharged from the surplus discharge duct 24 on the downstream side can be reused. Thus, as shown in FIG. 4, in this embodiment, the surplus-gas discharge duct 24 on the downstream side is connected to a reusable gas duct 46. A distal end of the reusable gas duct 46 is connected to the diluent gas duct 16 at a position on the immediately upstream side of the flow rate controller FC2. Namely, the surplus-gas discharge duct 24 is connected to the diluent gas duct 16 through the reusable gas duct 46.

As shown in FIG. 4, the reusable gas duct 46 is provided with a pressure pump 48, a filter 50, and an inline gas refiner 52. The pressure pump 48 is configured to increase a pressure of a discharged surplus gas. The filter 50 is configured to remove dusts slightly generated from the pressure pump 48, and to mitigate pressure vibrations of the pressure pump 48. The inline gas refiner 52 is configured to remove impurities such as a moisture in the gas. As the pressure pump 48, an oil-free pump and a dry pump such as a diaphragm pump are preferably used, in order to prevent oil from coming to be mixed in a gas.

On the downstream side of the inline gas refiner 52, connected to the reusable gas duct 46 is a surplus-gas discharge duct 54. The surplus-gas discharge duct 54 is provided with an opening and closing valve 56 and a check valve 58 in this order toward the downstream. Thus, the surplus gas, which has not been reused, can be discharged from the reusable gas duct 46 through the surplus-gas discharge duct 54.

In addition, between an outlet side of the inline gas refiner 22 disposed on the diluent gas duct 16 and a position at which the reusable gas duct 46 is connected to the diluent gas duct 16, the diluent gas duct 16 is provided with a check valve 60 and an opening and closing valve 62 in this order toward the downstream. Thus, when a flow rate of a gas flowing through the reusable gas duct 46 comes short, the deficit can be compensated by supplying a gas from the diluent gas tank 12. At the same time, a reusable gas will not flow into the diluent gas duct 36 connected to the mixer 38 at the latter step. Thus, although the reusable gas contains a some degree of O₂ gas, only a pure Ar gas can be flown into the diluent gas duct 36 connected to the mixer 38 at the latter step.

According to the third embodiment, the same operation and the same effect as those of the above second embodiment can be realized. In addition, due to the provision of the reusable gas duct 46, a part of the discharged surplus gas can be reused. Thus, an operation cost can be decreased.

### Fourth Embodiment

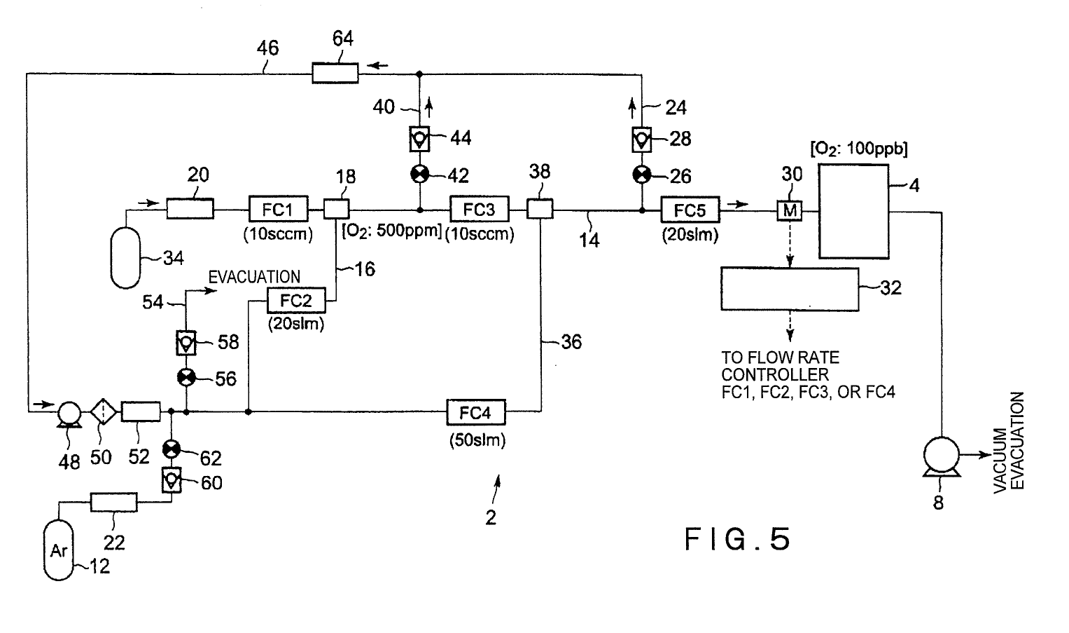

Next, a fourth embodiment of the process-gas supply system according to the present invention is described. FIG. 5 is a structural view showing the fourth embodiment of the process-gas supply system according to the present invention, which is connected to the processing apparatus 4. In FIG. 5, the same components as the components shown in FIGS. 1 to 4 are shown by the same reference numbers, and a detailed description thereof is omitted.

In the above third embodiment, although the surplus gas is discharged from the two surplus-gas discharge ducts 24 and 40, only the surplus gas having a lower O₂ density, which is discharged from the surplus-gas discharge duct 24, is reused. Meanwhile, in the fourth embodiment, the surplus gas discharged from both the two surplus-gas discharge ducts 24 and 40, i.e., all the surplus gas is reused. To be specific, the two surplus-gas discharge ducts 24 and 40 are respectively connected to the reusable gas duct 46. The other end of the reusable gas duct 46 is connected to the diluent gas duct 16. The reusable gas duct 46 in this embodiment is provided with a process-gas removal filter 64 configured to remove an O₂ gas as a process gas from the gas flowing through the reusable gas duct 46. Thus, only a diluent gas (Ar gas), from which O₂ has been removed, can be reused.

As described above, the reusable gas having passed through the process-gas removal filter 64 contains no O₂ component. Thus, the reusable gas having passed through the process-gas removal filter 64 comprises only a pure diluent gas (Ar). Therefore, the reusable gas can be introduced to the mixer 38 at the latter step. In the fourth embodiment, differently from the third embodiment in which a branch point at which the other diluent gas duct 36 is branched from the diluent gas duct 16 is located at a position on the immediately downstream side of the inline gas refiner 22 (see, FIG. 4), the branch point is located at a position on the immediately downstream side of the check valve 60 and the opening and closing valve 62 disposed on the downstream side of the inline gas refiner 22, i.e., at a position on the immediately upstream side of the flow rate controller FC2.

According to the fourth embodiment, the same operation and the same effect as those of the third embodiment can be realized. In addition, in the fourth embodiment, the reusable gas is supplied not only to the one diluent gas duct 16 but also to the other diluent gas duct 36. Thus, in the fourth embodiment, all the discharged surplus gas can be reused, whereby an operation cost can be further decreased.

### Fifth Embodiment

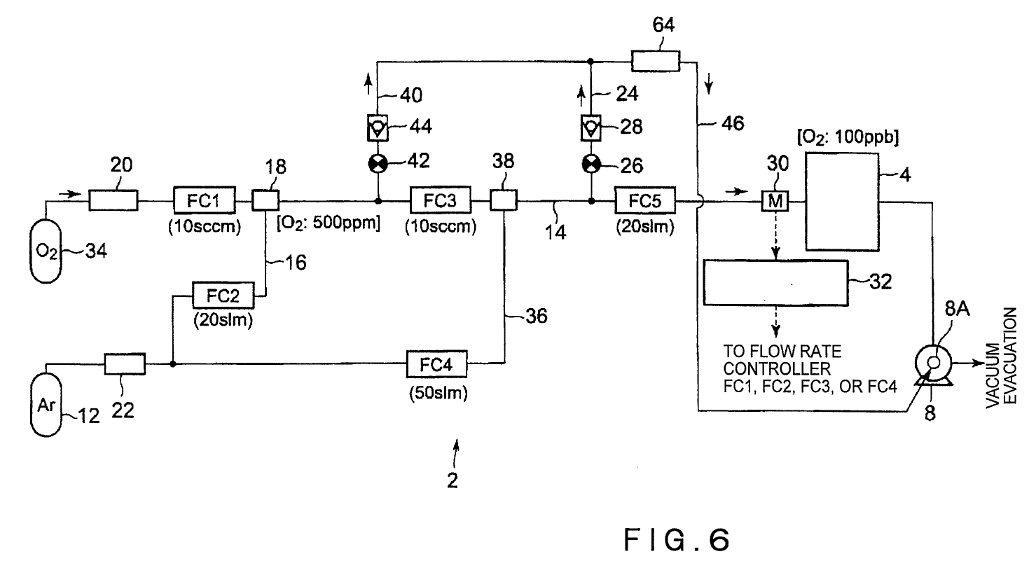

Next, a fifth embodiment of the process-gas supply system according to the present invention is described. FIG. 6 is a structural view showing the fifth embodiment of the process-gas supply system according to the present invention, which is connected to the processing apparatus 4. In FIG. 6, the same components as the components shown in FIGS. 1 to 5 are shown by the same reference numbers, and a detailed description thereof is omitted.

In the above fourth embodiment, the surplus-gas discharge ducts 24 and 40 are connected to the diluent gas duct 16 through the reusable gas duct 46, so that the surplus gas discharged outside the system can be reused as an Ar gas serving as a diluent gas. Meanwhile, in the fifth embodiment, as shown in FIG. 6, the reusable gas duct 46 connected to the surplus-gas discharge ducts 24 and 40 is connected to the vacuum pump 8 disposed on the processing apparatus 4, whereby the surplus gas can be used as a purge gas of a rotary shaft of the vacuum pump 8.

For example, when a semiconductor wafer is subjected to a film deposition process and an etching process, a reaction gas and a reaction byproduct remaining in the processing apparatus 4 are discharged as an exhaust gas. At this time, there is a possibility that the reaction gas and the reaction byproduct might adhere to the rotary shaft and the like of the vacuum pump 8 so as to damage the vacuum pump 8. In the fifth embodiment, in order to prevent the adhesion phenomenon, the surplus gas formed of a diluent gas having flown through the reusable gas duct 46 is used as a purge gas. To be specific, by blowing the surplus gas from the reusable gas duct 46 onto the rotary shaft 8A of the vacuum pump 8, the reaction gas and the reaction byproduct can be prevented from adhering to the rotary shaft.

In the fifth embodiment, since the surplus gas is not used as a diluent gas, it is not necessary to provide, on the duct of the surplus gas, the pressure pump 48, the filter 50, the inline gas refiner 52, the surplus-gas discharge duct 54, the opening and closing valves 56 and 62, and the check valves 58 and 60, which are provided in the third and fourth embodiments. In addition, the process-gas removal filter 64 for removing an O₂ component may be provided according to need.

According to the fifth embodiment, the same operation and the same effect as those of the above fourth embodiment can be realized. Although all the surplus gas is reused in this embodiment, the present invention is not limited thereto. Only the surplus gas discharged from one of the surplus-gas discharge ducts 24 and 40 may be reused. Further, in addition to the use of the surplus gas as a purge gas for the rotary shaft 8A of the vacuum pump 8, the surplus gas may be used for cooling an exhaust gas in a scrubber, and for diluting a combustible gas such as H₂ to a density less than an explosion lower limit.

### Sixth Embodiment

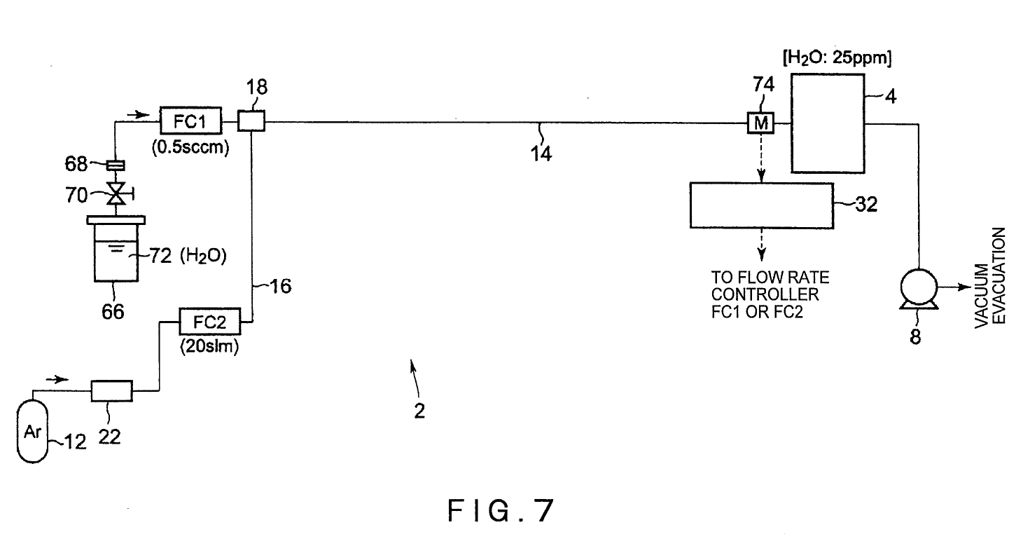

Next, a sixth embodiment of the process-gas supply system according to the present invention is described. In the sixth to tenth embodiments, there is described an example in which a moisture (steam) is used as a process gas. FIG. 7 is a structural view showing the sixth embodiment of the process-gas supply system according to the present invention, which is connected to the processing apparatus. In FIG. 7, the same components as the components shown in FIGS. 1 to 6 are shown by the same reference numbers, and a detailed description thereof is omitted.

The structure of the sixth embodiment shown in FIG. 7 is basically the same as the structure of the first embodiment shown in FIG. 1. However, in the sixth embodiment, there is provided, instead of the process gas tank 10 (see, FIG. 1), a liquid material tank 66 that stores a liquid material of a process gas (a material in a liquid state of a process gas). The liquid material tank 66 is detachably connected to the main gas duct 14 via a joint 68. When the liquid material tank 66 is attached and detached, an opening and closing valve 70 disposed on an outlet of the liquid material tank 66 can be manually opened and closed. The liquid material tank 66 is made of, e.g., stainless steel. A liquid material 72 is accommodated in the liquid material tank 66. In this embodiment, as described above, since a steam (water vapor) is used as a process gas, a purified water is used as the liquid material 72. A valve may be disposed between the joint 68 and the flow rate controller FC1, according to need.

Generated in the liquid material tank 66 is a vapor in accordance with a temperature of the liquid material 72, i.e., a steam in this embodiment. The inside of the liquid material tank 66 is maintained at a predetermined steam pressure. For example, a steam pressure at 35° C. is 45.1 Torr (6.0 KPa). In this embodiment, the generated steam, which is used as a process gas, flows downstream through the main gas duct 14. A supply amount of the steam (H₂O) flowing downstream through the main gas duct 14 can be suitably controlled by the flow rate controller FC1. If necessary, the liquid material tank 66 is equipped with a heater, so that the liquid material tank 66 can be heated by the heater to a predetermined temperature. In other words, the temperature of the liquid material tank 66 can be regulated such that a required steam pressure can be obtained by the heater. It may be necessary to prevent the steam of the liquid material from condensing inside the main gas duct 14. To this end, a heater is preferably provided in order that the main gas duct 14, and the flow rate controllers and the mixers disposed on the main gas duct 14 can be heated to a temperature close to that of the liquid material tank 66.

In this embodiment, all the steam, i.e., a process gas generated in the liquid material tank 66 can be used. Namely, the surplus-gas discharge duct 24 shown in FIG. 1 is not provided. The steam flowing downstream through the main gas duct 14 can be diluted with an Ar gas from the diluent gas duct 16. In addition, in this embodiment, a density measuring instrument 74 disposed on the main gas duct 14 at a position immediately before the processing apparatus 4 is configured to detect a density of moisture. Based on a detected value of a density of moisture, which is detected by the density measuring instrument 74, the feedback control part 32 controls the flow rate controller FC1 or the flow rate controller FC2.

In the sixth embodiment, a flow rate of the flow rate controller FC1 for a material gas is set at 0.5 sccm, and a flow rate of the flow rate controller FC2 for a diluent gas is set at 20 slm. Thus, a moisture density of the diluted process gas flowing downstream from the mixer 18 becomes 25 ppm, whereby the diluted process gas having a moisture density of 25 ppm is introduced into the processing apparatus 4. When the temperature of the liquid material 72 in the liquid material tank 66 is 35° C. as described above, the steam pressure is 45.1 Torr (6.0 KPa). This steam pressure is sufficient as a pressure for operating the flow rate controller FC1. Generally, in order that a flow rate controller can be operated, a differential pressure between a pressure on the upstream side of the flow rate controller and a pressure on the downstream side thereof should be a predetermined value or more. For this reason, the pressure on the downstream side of the flow rate controller FC1 is prevented from exceeding 45 Torr (6.0 KPa).

As described above, when a material of a process gas is the liquid material 72, a process gas (steam) generated from the liquid material tank 66 storing the liquid material is flown with a flow rate of the process gas being controlled, and the flowing process gas is diluted with a diluent gas with its flow rate being controlled. Thus, a density of the process gas can be precisely controlled within a significantly low density range from a several ppm level to a several hundreds ppm level. Further, since the density of the process gas to be introduced to the gas using system (processing apparatus 4) is detected for a feedback control, the density of the process gas can be precisely, stably controlled within a significantly low density range.

### Seventh Embodiment

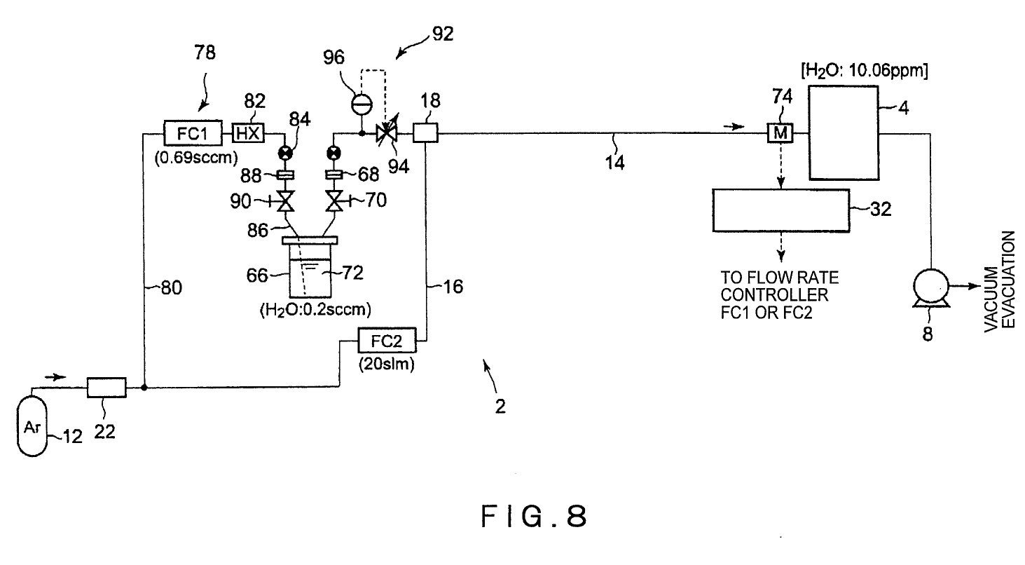

Next, a seventh embodiment of the process-gas supply system according to the present invention is described. FIG. 8 is a structural view showing the seventh embodiment of the process-gas supply system according to the present invention, which is connected to the processing apparatus 4. In FIG. 8, the same components as the components shown in FIGS. 1 to 7 are shown by the same reference numbers, and a detailed description thereof is omitted.

As shown in FIG. 8, in the seventh embodiment, a bubbling mechanism 78 is disposed on the liquid material tank 66 which is described in the sixth embodiment shown in FIG. 7. To be specific, the bubbling mechanism 78 has a bubbling gas duct 80 branched from the diluent gas duct 16. Namely, in this embodiment, an Ar gas is used as a bubbling gas. The bubbling gas duct 80 is provided with the flow rate controller FC1, a heat exchanger 82, and an opening and closing valve 84 in this order toward the downstream. The heat exchanger 82 is configured to maintain a bubbling gas at a predetermined temperature.

As shown in FIG. 8, one end of the bubbling gas duct 80 is connected, via a joint 88, to a bubbling nozzle 86 disposed in the liquid material tank 66. A distal end of the bubbling nozzle 86 is immersed in the liquid material 72 accommodated in the liquid material tank 66. The bubbling nozzle 86 is provided with a manually operable opening and closing valve 90.

On the other hand, instead of the flow rate controller FC1 shown in FIG. 7, the main gas duct 14 is provided with a pressure regulating valve mechanism 92. The pressure regulating valve mechanism 92 includes a pressure regulating valve 94 and a pressure measuring instrument 96 disposed on the main gas duct 14. The pressure regulating valve 94 is configured to be controlled based on a pressure value obtained by the pressure measuring instrument 96. In this embodiment, a pressure in the main gas duct 14 is controlled to, e.g., a range between 1 and 50 kPa by the pressure regulating valve mechanism 92.

In the seventh embodiment, a flow rate of the flow rate controller FC1 is set at 0.69 sccm, and a flow rate of the flow rate controller FC2 is set at 20 slm. Further, a temperature of the material liquid 72 is set at 35° C., and an inside pressure of the liquid material tank 66 is set at 200 Torr (26.7 KPa). In this case, an actual flow rate of moisture in the steam, which has been generated by bubbling with the use an Ar gas, becomes 0.20 sccm. As a result, a moisture density of the gas to be introduced to the processing apparatus 4 becomes 10.06 ppm.

The diluted process gas containing the generated steam is further diluted with an Ar gas in the mixer 18, and is supplied to the processing apparatus 4. In this embodiment, the feedback control part 32 feedback-controls the flow rate controller FC1 or the flow rate controller FC2. As described above, in this embodiment, when a material of a process gas is the liquid material 72, a diluent gas whose flow rate has been controlled is introduced into the liquid material tank 66 storing the liquid material 72 so as to form a process gas (steam) by bubbling, and the process gas is further diluted with a diluent gas whose flow rate has been controlled. Thus, a density of the process gas can be precisely controlled within a significantly low density range from a several ppm level to a several hundreds ppm level.

Further, since the density of the process gas to be introduced to the gas using system (processing apparatus 4) is detected for a feedback control, the density of the process gas can be precisely, stably controlled within a significantly low density range.

### Eighth Embodiment

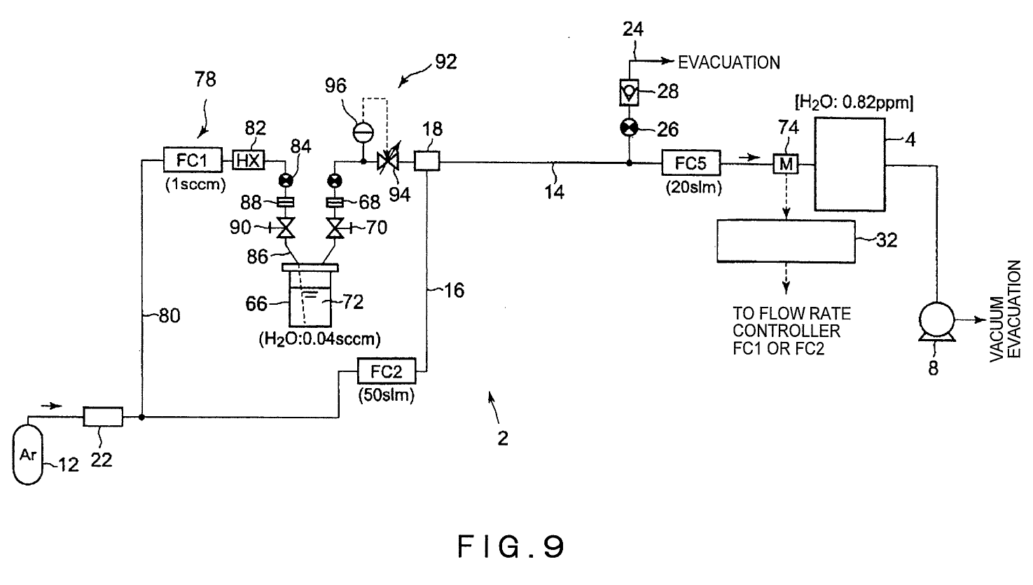

Next, an eighth embodiment of the process-gas supply system according to the present invention is described. FIG. 9 is a structural view showing the eighth embodiment of the process-gas supply system according to the present invention, which is connected to the processing apparatus 4. In FIG. 9, the same components as the components shown in FIGS. 1 to 8 are shown by the same reference numbers, and a detailed description thereof is omitted.

As shown in FIG. 9, differently from the structure of the seventh embodiment shown in FIG. 8, in the eighth embodiment, the main gas duct 14 is provided with a flow rate controller FC5. Moreover, in the eighth embodiment, the surplus-gas discharge duct 24 having the opening and closing valve 26 and the check valve 28 is branched from the main gas duct 14 at a position on the immediately upstream side of the flow rate controller FC5. A surplus gas of the diluted process gas containing a steam, which remains in a part of the main gas duct 14 on the upstream side of the flow rate controller FC5, can be discharged through the surplus-gas discharge duct 24.

Set values of the flow rate controllers FC1, FC2, and FC5 in the eighth embodiment are 1 sccm, 50 slm, and 20 slm, respectively. A temperature of the material liquid 72 is set at 35° C., and an inside pressure of the liquid material tank 66 is set at 1140 Torr (152 KPa). In this case, an actual flow rate of moisture in the steam, which is generated by bubbling with the use of an Ar gas, becomes 0.04 sccm. As a result, a moisture density of the gas to be introduced to the processing apparatus 4 becomes 0.82 ppm.

According to the eighth embodiment, the same operation and the same effect as those of the seventh embodiment shown in FIG. 8 can be realized.

In the eighth embodiment, a pressure range controlled by the pressure regulating valve mechanism 92 is set higher than that of the seventh embodiment, i.e., the pressure control range is between 10 and 500 kPa, for example. Thus, an amount of steam to be generated is reduced, whereby the density of the process gas can be controlled within a density range that is further lower than the density range of the seventh embodiment.

### Ninth Embodiment

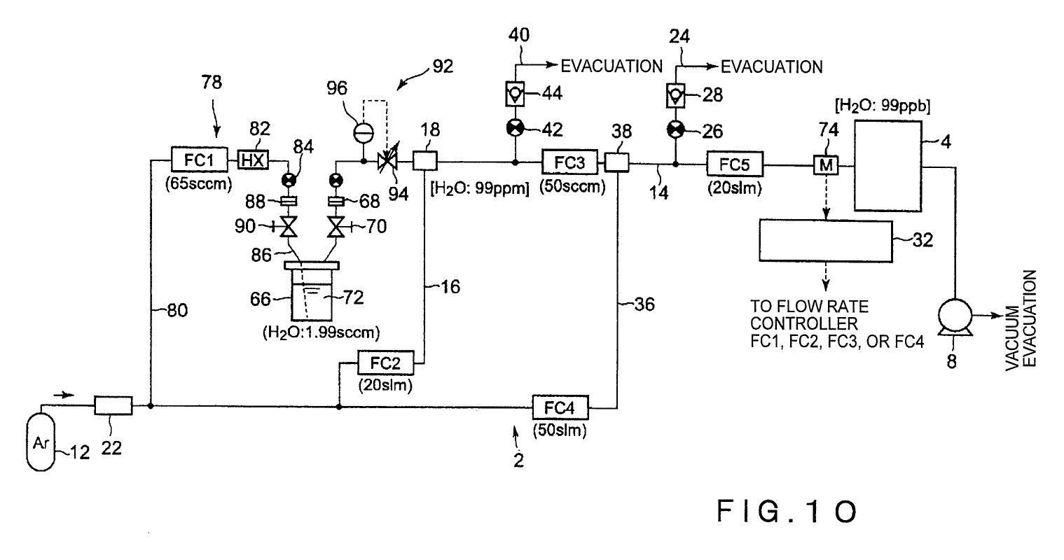

Next, a ninth embodiment of the process-gas supply system according to the present invention is described. FIG. 10 is a structural view showing the ninth embodiment of the process-gas supply system according to the present invention. In FIG. 10, the same components as the components shown in FIGS. 1 to 9 are shown by the same reference numbers, and a detailed description thereof is omitted.

As shown in FIG. 10, differently from the eighth embodiment shown in FIG. 9, in the ninth embodiment, there are further provided the new diluent gas duct 36 the flow rate controller FC4 disposed on the diluent gas duct 36, the mixer 38 and the flow rate controller FC3 which are disposed on the main gas duct 14, and the new surplus-gas discharge duct 40 provided with the opening and closing valve 42 and the check valve 44, which have been already described in the second embodiment shown in FIG. 3.

Set values of the flow rate controllers FC1 to FC5 in the ninth embodiment are 65 sccm, 20 slm, 50 sccm, 50 slm, and 20 slm, respectively. A temperature of the material liquid 72 is set at 35° C., and an inside pressure of the liquid material tank 66 is set at 1520 Torr (203 KPa). In this case, an actual flow rate of moisture in the steam, which is generated by bubbling with the use of an Ar gas, becomes 1.99 sccm. As a result, a moisture density of the gas to be introduced to the processing apparatus 4 becomes 99 ppb.

As described above, in this embodiment, the diluent gas ducts 16 and 36 and the surplus-gas discharge ducts 24 and 40 are disposed in a stepwise manner, e.g., in two steps, so that the process gas is repeatedly diluted in a stepwise manner, e.g., in two steps, while dilution of the process gas (steam) and discharge of the surplus gas are repeated. Thus, a density of the process gas can be precisely controlled within a further lower density range. In addition, since the density of the process gas to be introduced to the gas using system (processing apparatus 4) is detected for a feedback control, the density of the process gas can be precisely, stably controlled within a significantly low density range.

### Tenth Embodiment

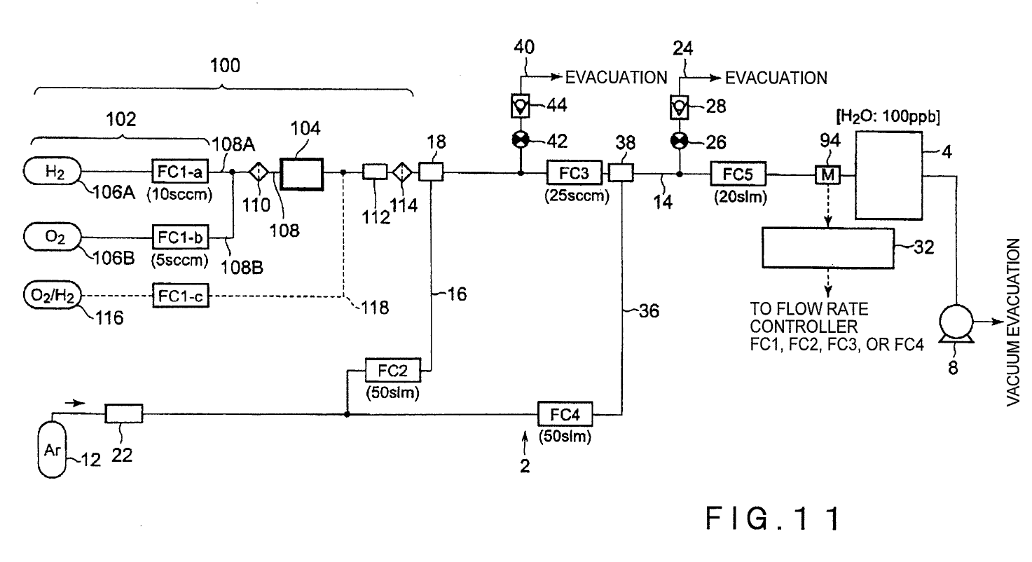

Next, a tenth embodiment of the process-gas supply system according to the present invention is described. FIG. 11 is a structural view showing the tenth embodiment of the process-gas supply system according to the present invention, which is connected to the processing apparatus 4. In FIG. 11, the same components as the components shown in FIGS. 1 to 10 are shown by the same reference numbers, and a detailed description thereof is omitted.

As shown in FIG. 11, instead of the liquid material tank 66 and the bubbling mechanism 78 in the ninth embodiment shown in FIG. 10, in the tenth embodiment, a process-gas forming part (a process-gas forming unit) 100 of another mechanism is provided. In the eighth embodiment shown in FIG. 9, the process-gas forming part 100 in this embodiment may be provided, instead of the liquid material tank 66 and the bubbling mechanism 78.

To be specific, as shown in FIG. 11, the process-gas forming part 100 includes a material-gas supply system 102 and a reaction part 104 (reaction unit, reactor). The material-gas supply system 102 is configured to supply a plurality of material gases for forming a process gas, while independently controlling flow rates of the material gases. The reaction part 104 is configured to form the process gas by reacting the plurality of material gases supplied from the material-gas supply system 102.

In the example shown in FIG. 11, two material gas tanks 106A and 106B each storing a material gas are disposed as the material-gas supply system 102. For example, a pure H₂ gas is stored in the one material gas tank 106A, and a pure O₂ gas is stored in the other material gas tank 106B. Tanks of a factory equipment may be used as these material gas tanks 106A and 106B. A gas duct 108A, which is extended from the material gas tank 106A, and a gas duct 108B, which is extended from material gas tank 106B, are merged into a gas duct 108. The gas duct 108 is provided with the reaction part 104.

In the reaction part 104, a process gas, e.g., a steam in the illustrated example, is formed by a catalyst reaction or a combustion reaction. The gas duct 108 is connected to the main gas duct 14, so that a steam as a process can be flown downstream.

As shown in FIG. 11, the gas ducts 108A and 108B are provided with flow rate controllers FC1-a and FC1-b, respectively. The flow rate controllers FC1-a and FC1-b are configured to control flow rates of gases flowing through the respective gas ducts 108A and 108B. At a position on the immediately upstream side of the reaction part 104, the gas duct 108 is provided with a filter 110. Further, at a position on the immediately downstream side of the reaction part 104, the gas duct 108 is provided with a sensor 112 for detecting H₂ or O₂, and a filter 114.

If necessary, an additional gas tank 116 storing an O₂ gas or an H₂ gas may be provided, and a gas duct 118 provided with a flow rate controller FC1-c may be extended from the tank 116, such that a distal end of the gas duct 118 is connected to the gas duct 108 at a position on the downstream side of the reaction part 104. In addition to a gas flowing from the reaction part 104, an O₂ gas or an H₂ gas may be supplied as an additional gas.

A set value of the flow rate controller FC1-a is 10 sccm, a set value of the flow rate controller FC1-b is 5 sccm, a set value of the flow rate controller FC2 is 50 slm, a set value of the flow rate controller FC3 is 25 sccm, a set value of the flow rate controller FC4 is 50 slm, and a set value of the flow rate controller FC5 is 20 slm. An amount of water generated in the reaction part 104 by a catalyst reaction or a combustion reaction is 10 sccm. A surplus diluted process gas is discharged through the surplus-gas discharge ducts 24 and 40, which is as described above. As a result, a moisture density in the gas to be introduced to the processing apparatus 4 becomes 100 ppb.

In this embodiment, by diluting the process gas (steam) flowing through the main gas duct 14 from the process-gas forming part 100 with a diluent gas which has flown through the diluent gas ducts 16 and 36 with a flow rate of the diluent gas being controlled, a diluted process gas having a regulated density can be generated. In addition, the diluted process gas is supplied with its flow rate being controlled, as well as the surplus diluted process gas is discharged. Thus, a density of the process gas can be precisely controlled within a significantly low density range from a several ppb level to a several hundreds ppb level.

Moreover, in the process-gas forming part 100, a process gas is formed by supplying a plurality of material gases, e.g., an O₂ gas and an H₂ gas, for forming the process gas, and by reacting these material gases in the reaction part 104. Thus, a purity of the process gas formed in the reaction part 104 can be maintained high. In addition, due to the two flow rate controllers FC1-a and FC1-b through which the material gases are supplied, flow rates of the material gases can be precisely controlled, whereby a flow rate of the process gas (moisture=steam) generated by the reaction between these gases can be precisely controlled.

A feedback of the feedback control part 32 for regulating a moisture density of the gas is fed to any one of the flow rate controllers FC2, FC3, and FC4. Owing to this feedback control, although the moisture density of the gas resides in a significantly low density range, the moisture density can be precisely stably controlled. In order to regulate the moisture density, the flow rate controller FC1-a or the flow rate controller FC1-b may be feedback-controlled. A micro-evaporator of a permeable film type, which is called Permeater, may be used a the process-gas forming part 100. Also in this case, the same operation and the same effect as those of the aforementioned embodiments can be realized.

### Eleventh Embodiment

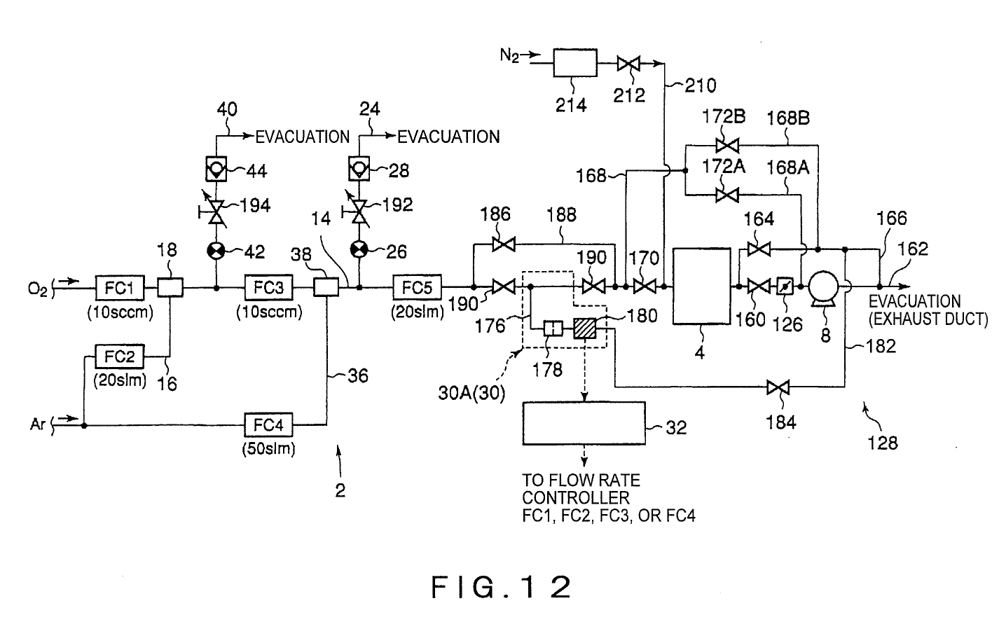

Next, an eleventh embodiment of the process-gas supply system according to the present invention is described. FIG. 12 is a partial structural view showing the eleventh embodiment of the process-gas supply system according to the present invention. In FIG. 12, the same components as the components of the second embodiment shown in FIG. 3 are shown by the same reference numbers, and a detailed description thereof is omitted. The eleventh embodiment is obtained by modifying the second embodiment, which has been described with reference to FIG. 3, as a basic structure. In the processing apparatus 4, an annealing process can be performed not only under a vacuum atmosphere but also under an atmospheric pressure or a near atmospheric pressure. At the same time, a pressure variation on the upstream side of each flow rate controller is restrained so as to guarantee a stable operation of each flow rate controller.

Herein, in order that an annealing process can be selectively performed not only under a vacuum atmosphere but also under an atmospheric pressure or a near atmospheric pressure, a vacuum exhaust system (exhaust system) includes two lines. That is to say, connected to the processing apparatus 4 as a gas using system is a vacuum exhaust system 128 that discharges an inside atmosphere of the processing apparatus 4. The vacuum exhaust system 128 includes a main exhaust duct 162 provided with an opening and closing valve 160, a pressure regulating valve 126 for regulating a pressure in the processing apparatus (processing container) 4, and a vacuum pump 8 such as a dry pump, in this order toward the downstream side. The downstream side of the main exhaust duct 162 is connected to an exhaust duct maintained at about an atmospheric pressure, via a scrubber, not shown. An exhaust gas from the processing container 4 is released in the atmosphere through the not-shown exhaust duct.

The main exhaust duct 162 has a bypass exhaust duct 166 that bypasses the vacuum pump 8. The bypass exhaust duct 166 is provided with an opening and closing valve 164. To be specific, one upstream end of the bypass exhaust duct 166 is connected to the main exhaust duct 162 at a position on the upstream side of the opening and closing valve 160, and the other downstream end thereof is connected to the main exhaust duct 162 at a position on the downstream side of the vacuum pump 8. Thus, when an annealing process is performed in the processing apparatus 4 under a vacuum atmosphere, the opening and closing valve on the bypass exhaust duct 166 is closed, and the opening and closing valve 160 on the main exhaust duct 162 is opened. Then, by driving the vacuum pump 8 so as to rotate the same, an annealing process can be performed under a vacuum atmosphere.

On the other hand, when an annealing process is performed in the processing apparatus 4 under an atmospheric pressure or an almost atmospheric pressure, the opening and closing valve 164 on the bypass exhaust duct 166 is opened, and the opening and closing valve 160 on the main exhaust duct 162 is closed, which is contrary to the above. Thus, an atmosphere in the processing apparatus 4 is directly sucked from the exhaust duct, so that an annealing process can be performed under an atmospheric pressure or an almost atmospheric pressure. In other words, an annealing process can be performed under a wide pressure atmosphere ranging from a vacuum atmosphere to an atmospheric pressure. The structure of the vacuum exhaust system can be applied to all the first to tenth embodiments.

When a density of a process gas, such as an oxygen density, is changed, or when the processing system is activated, a flow rate becomes sometimes temporarily unstable. In this case, it is sometimes necessary to bypass the process gas so as to be discarded, without the process gas flowing into the processing apparatus 4. Thus, a discarded-gas discharge duct 168 through which a process gas to be discarded flows is connected to the main gas duct 14 of the process-gas supply system at a position immediately before the processing apparatus 4. An opening and closing valve 170 is disposed on the main gas duct 14 at a position between the connection point to which the discarded-gas discharge duct 168 is connected and the processing apparatus 4. When a process gas is discarded, the opening and closing valve 170 is closed such that the process gas cannot flow to the processing apparatus 4. Of course, when a process gas is flown to the processing apparatus 4, the opening and closing valve 170 is opened.

The discarded-gas discharge duct 168 is branched into two branch ducts 168A and 168B. A downstream side of the one branch duct 168A is connected to the main exhaust duct 162 at a position on the immediately upstream side of the vacuum pump 8. A downstream side of the other branch duct 168B is connected to the bypass exhaust duct 166 on the downstream side of the opening and closing valve 164. The one branch duct 168A is provided with an opening and closing valve 172A for vacuum atmosphere, and the other branch duct 168B is provided with an opening and closing valve 172B for atmospheric pressure. Thus, at the start of an annealing process to be performed under a vacuum atmosphere, an unnecessary process gas (a process gas whose flow rate is unstable) is discarded to the main exhaust duct 162 through the branch duct 168A, by opening the opening and closing valve 172A for vacuum atmosphere.

At the start of an annealing process to be performed under an atmospheric pressure, an unnecessary process gas (a process gas whose flow rate is unstable) is discarded to the bypass exhaust duct 166 through the branch duct 168B, by opening the opening and closing valve 172B for atmospheric pressure. The series of the structure of the discarded-gas discharge duct 168 can be applied to all the aforementioned first to tenth embodiments.

Herein, as the density measuring instrument 30 for measuring an O₂ density, a density measuring instrument 30A of a zirconia type is disclosed, for example. The zirconia-type density measuring instrument 30A has a branch measuring pipe 176 by which a part of a process gas flowing through the main gas duct 14 is branched and taken out. The branch measuring pipe 176 is provided with an orifice 178 and a zirconia-type O₂ measuring sensor 180. By using the density measuring instrument 30A as structured above, an O₂ density of the process gas can be measured.

In such a density measuring instrument 30A, a flow rate of the process gas, which has been branched and flown into the branch measuring pipe 176, is strictly limited, because of the provision of the orifice 178. For example a flow rate of the gas flowing through the branch measuring pipe 176 is very small, which is as low as about 10% of a flow rate of the gas flowing through the main gas duct 14. Thus, an adverse effect to the annealing process in the processing apparatus 4 can be prevented.

In the zirconia-type O₂ measuring sensor 180, an O₂ density of the gas to be measured tends to somewhat increase, which arises from a measuring method of the sensor 180. Thus, it is undesirable that the gas whose O₂ density have been measured is returned to the main gas duct 14. In this embodiment, the gas flowing into the branch measuring pipe 176 is sent to the vacuum exhaust system 128 so as to be discarded. To be specific, a downstream side of the branch measuring pipe 176 is connected to the bypass exhaust duct 166 through a pipe 182 provided with an opening and closing valve 184.

Due to the above structure, when an annealing process is performed in the processing apparatus 4 under an atmospheric pressure, the process gas whose O₂ density has been measured by the density measuring instrument 30A is sent to the bypass exhaust duct 166 through the pipe 182 so as to be discarded.

Under a vacuum pressure, the zirconia-type O₂ measuring sensor 180 cannot be used, or it is sometimes unnecessary to measure an O₂ density of the process gas. For this case, connected to the main gas duct 14 is a measuring-instrument bypass pipe 188 provided with an opening and closing valve 186, in order that the process gas can bypass the zirconia-type density measuring instrument 30 (30A).

In addition, opening and closing valves 190 are disposed on the main gas duct 14 on the immediately upstream side and the immediately downstream side of the zirconia-type density measuring instrument 30 (30A). By switching these opening and closing valves 190 and the opening and closing valve 186 disposed on the measuring-instrument bypass pipe 188, it can be selected whether to measure an O₂ density of the process gas or not.

A value measured by the zirconia-type O₂ measuring sensor 180 is inputted to the feedback control part 32. Then, any one of the flow rate controllers FC1 to FC4 is controlled by the feedback control part 32, so as to maintain constant the O₂ density at a predetermined value.

Flow rates to be controlled by the flow rate controllers FC2 and FC4 are larger than 1000 times or more than flow rates to be controlled by the flow rate controllers FC1 and FC3. Thus, when an O₂ density is regulated, the flow rates of the flow rate controllers FC1 and FC3, which are small flow rates, are controlled, while fixedly maintaining the flow rates of the flow rate controllers FC2 and FC4. A gas duct length from the flow rate controller FC1 to the processing apparatus 4 is longer than that from the flow rate controller FC3 to the processing apparatus 4. Thus, when an O₂ density is regulated by controlling the flow rate of the flow rate controller FC1, a long period of time is required to reflect an O₂ density in the processing apparatus 4 as a result of the regulation. As a result, it is most preferable to control an O₂ density by controlling the flow rate of the flow rate controller FC3. The structure of the zirconia-type density measuring instrument 30 (30A) can be applied to all the first to tenth embodiments, when an O₂ density is measured.

In addition, the surplus-gas discharge ducts 24 and 40 are provided with the check valves 28 and 44, respectively, which are opened when a pressure in the main gas duct 14 reaches or exceeds a predetermined pressure. Further, in this embodiment, needle valves 192 and 194 are disposed on the surplus-gas discharge ducts 24 and 40 on the upstream sides of the check valves 28 and 44, respectively. Due to the needle valves 192 and 194, even when the respective check valves 28 and 44 are opened, a pressure in the main gas duct 14 is prevented from declining abruptly, but declines slowly.

In general, when a pressure is largely varied between the downstream side and the upstream side of a mass flow controller such as the flow rate controllers FC3 and FC5, it is known that a precision of flow rate control is degraded. However, since the surplus-gas discharge ducts 24 and 40 are provided with the needle valves 192 and 194, even when the respective check valves 28 and 44 are opened, a pressure in the main gas duct 14 declines not abruptly but slowly. Thus, a pressure variation on the upstream sides of the flow rate controllers FC3 and FC5 can be restrained. As a result, a precision of flow rate control of each flow rate controller FC3 and FC5 can be maintained excellent. The structure of each needle valve 192 and 194 can be applied to all the first to tenth embodiments.

A purge line 210 with the use of an inert gas is connected to the most downstream side of the main gas duct 14. The purge line 210 is provided with an opening and closing valve 212 and a flow rate controller 214 such as a mass flow controller. According to the purge line 210, discharge of a gas remaining in the processing apparatus 4 can be promoted, according to need, by flowing therethrough a purge gas. An inert gas such as an N₂ gas and a rare gas such as Ar may be used as a purge gas.

### Twelfth Embodiment

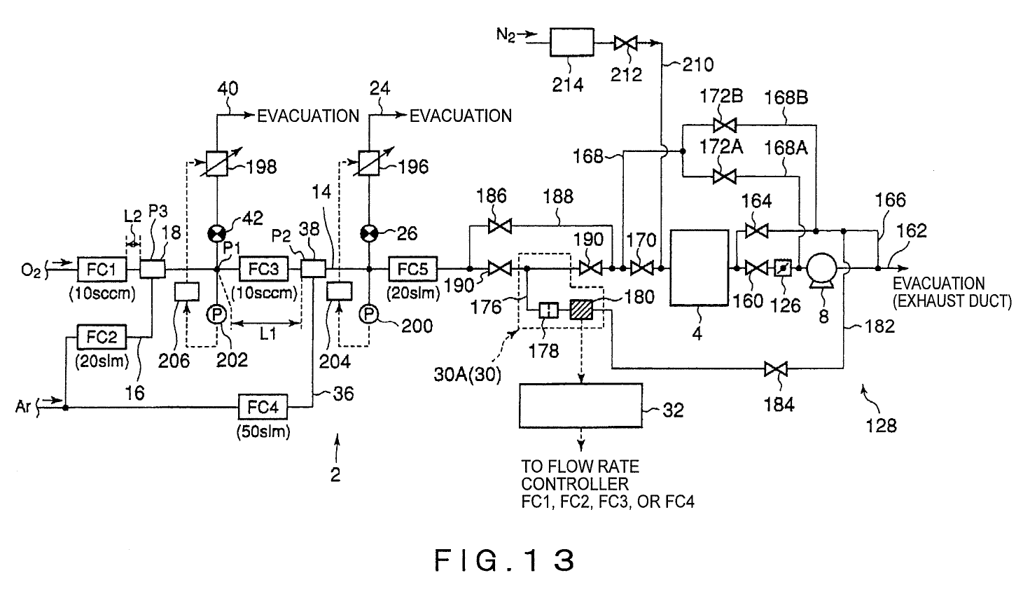

Next, a twelfth embodiment of the process-gas supply system according to the present invention is described. FIG. 13 is a partial structural view showing the twelfth embodiment of the process-gas supply system according to the present invention. In FIG. 13, the same components as the components shown in FIGS. 3 and 12 are shown by the same reference numbers, and a detailed description thereof is omitted. In the twelfth embodiment, a pressure variation on the upstream side of each flow rate controller is further restrained.

In this embodiment, the surplus-gas discharge ducts 24 and 40 are provided with pressure regulating valves 196 and 198, instead of the check valves 28 and 44 and the needle valves 192 and 194, which are shown in FIG. 12. A pressure in the main gas duct 14 can be controlled by the pressure regulating valves 196 and 198 to a predetermined value. In this embodiment, pressure gauges 200 and 202 are disposed on the main gas duct 14 at positions on the immediately upstream sides of the flow rate controllers FC5 and FC3. Values measured by these pressure gauges 200 and 202 are inputted to valve control devices (valve controlling parts) 204 and 206, respectively. The valve control devices 204 and 206 are configured to independently control the pressure regulating valves 196 and 198.

According to such a structure, pressures on the upstream sides of the flow rate controllers FC5 and FC3 can be maintained constant all the time by the operations of the pressure regulating valves 196 and 198. Thus, as compared with the eleventh embodiment, the operations of the respective flow rate controllers FC5 and FC3 can be further stabilized. Thus, a precision of flow rate control by the flow rate controllers FC5 and FC3 can be more improved. The structure of each pressure regulating valve 196 and 198 can be applied to all the first to tenth embodiments.

It is preferable that an overall length of the main gas duct 14 is reduced as much as possible, so that a volume of the inside of the duct is decreased as much as possible, in order that an oxygen density of a process gas is rapidly changed so as to enhance a throughput.

Further, in this embodiment, in order to more accelerate the regulation of an oxygen density, an inside diameter of a part of the main gas duct 14, which is located between a connection point P1 at which the surplus-gas discharge duct 40 is connected to the main gas duct 14, and a connection point P2 on the downstream side of the connection point P1 along the main gas duct 14, at which the diluent gas duct 36 is connected to the main gas duct 14, is smaller than an inside diameter of another part of the main gas duct 14.

To be specific, a part L1 of the main gas duct 14, which is located between the connection point P1 at which the surplus-gas discharge duct 40 is connected to the main gas duct 14, and the connection point P2 (specifically, the mixer 38) on the downstream side of the connection point P1 along the main gas duct 14, at which the diluent gas duct 36 is connected to the main gas duct 14, has an inside diameter smaller than that of another part of the main gas duct 14. For example, the main gas duct 14 is mainly formed of a pipe having a pipe diameter of, e.g., ¼ inch. On the other hand, the part L1 of the main gas duct 14 is formed of a pipe having a pipe diameter of ⅛ inch. Due to this structure, when an O₂ density of the process gas is changed, the process gas in the part L1 of the main gas duct 14 can be rapidly replaced, because the volume of the part L1 is very small.

In addition, similarly to the above, a part L2 of the main gas duct 14, which is located between the flow rate controller FC1 and a connection point P3 (mixer 18) on the immediately downstream side of the flow rate controller FC1, to which the diluent gas duct 16 is connected, may have a different pipe diameter. O₂ of 100% density remains in the part L2 of the main gas duct 14. When the part L2 of the main gas duct 14 is formed of a pipe having a pipe diameter of ⅛ inch, the replacement of the process gas in the part L2 of the main gas duct 14 can be accelerated.

In this manner, a pipe diameter of the pipe forming the main gas duct is partially changed, so as to further accelerate the regulation of an oxygen density. This structure can be applied to the first to tenth embodiments.

<Processing Apparatus as Gas Using System>

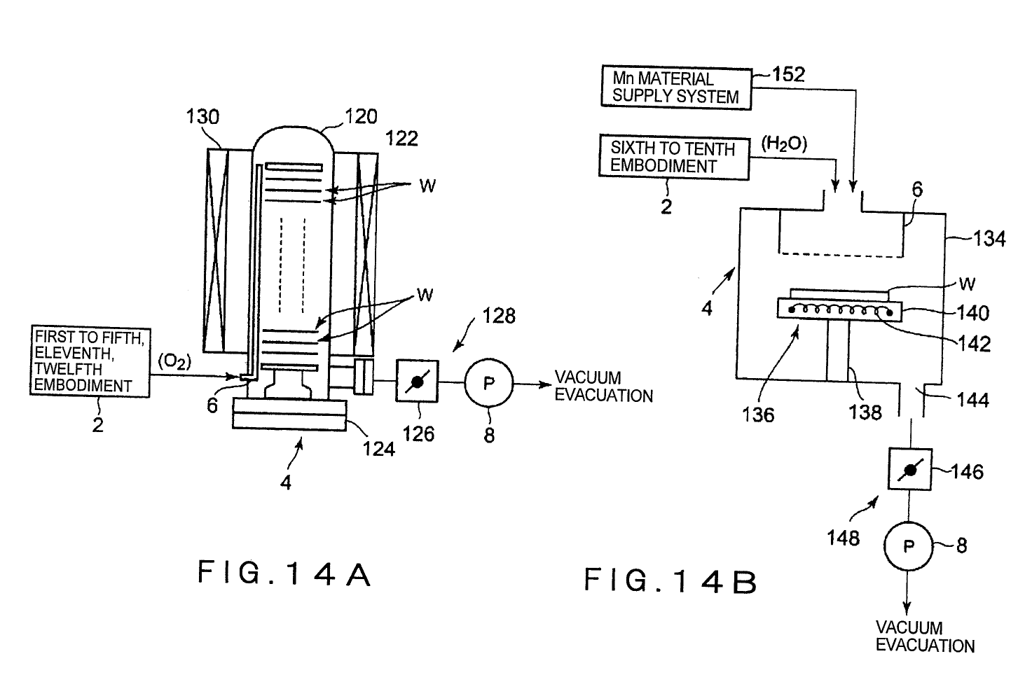

Next, there is described an example of the processing apparatus 4 which is a gas using system using one of the first to twelfth embodiments of the process-gas supply system 2. FIG. 14 is a schematic structural view showing an example of the processing apparatus which is a gas using system. FIG. 14A shows an example of a processing apparatus of a batch type, which is configured to simultaneously process a plurality of objects to be processed. FIG. 14B shows an example of a processing apparatus of a single wafer type, which is configured to process objects to be processed one by one.

The processing apparatus 4 shown in FIG. 14A is a processing apparatus configured to perform an annealing process, for example. The processing apparatus 4 includes a cylindrical quartz processing container 120 made of quartz. For example, the quartz processing container 120 has a ceiling part, with a lower end thereof being opened. The processing apparatus 4 is equipped with a holding mechanism 122 such as a wafer boat. The holding mechanism 122 is adapted to be capable of being moved upward from below the processing container 120 to an inside of the processing container 120, and capable of being moved downward from the inside of the processing container 120 to an outside of the processing container 122. Thus, the holding mechanism 122 can be loaded into and unloaded from the processing container 120. The lower end of the processing container 120 is hermetically sealed by a lid part 124. A plurality of semiconductor wafers W as objects to be processed are supported by the holding mechanism 122 in a tier-like manner.

A vacuum exhaust system 128 provided with a pressure regulating valve 126 and a vacuum pump 8 is connected to a lower part of the processing container 120. The inside of the processing container 120 is vacuumized by the vacuum exhaust system 128, such that the inside of the processing container 120 can be maintained at a predetermined reduced pressure atmosphere. A cylindrical heating apparatus 130 is disposed so as to surround an outer circumference of the processing container 120. The wafers W can be heated by the heating apparatus 130. The processing container 120 has a gas introduction member 6 for introducing a gas into the processing container 120. The gas introduction member 6 is structured as a gas nozzle extending along in the processing container 120 an up and down direction thereof.

Connected to the gas introduction member 6 is the process-gas supply system 2 in any one of the first to fifth, the eleventh, and the twelfth embodiments. As described above, the process-gas supply system 2 is adapted to supply, as a process gas, a gas whose O₂ density has been controlled to a significantly slight one. In particular, when an amount of gas to be supplied from the process-gas supply system 2 is large, there is a possibility that a temperature atmosphere in the processing container might be cooled by the gas supplied from the process-gas supply system 2. From the viewpoint of preventing the decrease in temperature of the temperature atmosphere in the processing container, a heat exchanger (gas heating apparatus) for previously heating a gas is preferably disposed on the main gas duct 14 at any position from the flow rate controller FC5 to the gas introduction member 6 via the density measuring instrument 30.

With the use of the processing apparatus, an annealing process can be performed to semiconductor wafers W on which Mn films and CuMn films have been formed, under an atmosphere whose O₂ density has been controlled to a significantly thin one. If necessary, another process gas can be supplied into the processing container 120 as a matter of course. Alternatively, the annealing process may be performed by the processing apparatus of a single wafer type, which is shown in FIG. 14B.

The processing apparatus shown in FIG. 14B is a processing apparatus configured to deposit a film, e.g., a film containing Mn. The processing apparatus 4 includes a cylindrical processing container 134 made of, e.g., an aluminium alloy. Provided in the processing container 134 is a holding mechanism 136 configured to hold a semiconductor wafer W as an object to be processed. To be specific, the holding mechanism 136 has a discoid stage 140 standing from a bottom of the container by a column 138. The stage 140 is adapted to be capable of holding a wafer W that is placed thereon. In the stage 140, there is provided a heating apparatus 142 formed of, e.g., a tungsten wire. The wafer W can be heated by the heating apparatus 142.

An exhaust port 144 is formed in the bottom of the processing container 134. Connected to the exhaust port 144 is a vacuum exhaust system 148 provided with a pressure regulating valve 146 and a vacuum pump 8. An inside of the processing container 134 is vacuumized by the vacuum exhaust system 148, such that the inside of the processing container 134 is maintained at a predetermined reduced pressure atmosphere. In order to operate the pressure regulating valve 146, a pressure gauge, not shown, is disposed in the processing container 134. In a step where a process gas is unnecessary, the vacuum exhaust system 148 should rapidly discharge the process gas from the inside of the processing container 134. Thus, according to need, there may be disposed a high vacuum exhaust system such as a turbo molecular pump (TMP), an ion pump, a sputter ion pump, a noble pump, a titanium sublimation pump, and a cryopump.

A gas introduction member 6 formed of, e.g., a showerhead is disposed on a ceiling part of the processing container 134. A required gas can be supplied into the processing container 134 via the gas introduction member 6. As shown in FIG. 14B, connected to the gas introduction member 6 is a Mn material supply system 152 and the process-gas supply system 2 in any one of the sixth to tenth embodiments. As described above, the process-gas supply system 2 is adapted to supply, as a process gas, a gas whose H₂O density has been controlled to a significantly slight one.

The Mn material supply system 152 is made to supply, for example, a Mn organic metal material as a Mn material, and is configured to supply the gas with its flow rate being controlled. In this embodiment, there is employed a post-mix supply method in which H₂O and the Mn material, which have separately flown through the showerhead (gas introduction member) 6, are mixed for the first time in the processing container 134.

With the use of the processing apparatus, a Mn containing film of a good quality can be formed on the semiconductor wafer W, the film having a precisely regulated film thickness. If necessary, another process gas can be supplied into the processing container 120 as a matter of course. Alternatively, the film deposition process may be performed by the processing apparatus of a batch type, which is shown in FIG. 14A. Further, in the respective aforementioned embodiments, an Ar gas is used as a diluent gas, which is by way of example. Not limited thereto, one or more gases selected from the group consisting of N₂ and a rare gas (Ar, Ne, He, Xe, and so on) may be used as a diluent gas.

The above-described flow rates of the gases and the gas densities are merely taken as examples, and the present invention is not naturally limited to these numerical examples. In addition, in the above embodiments, although there have been described the examples in which a film such as a Mn containing film and a CuMn film is annealed, another film such as a Cu film, a Co film, a W film, an Al film, and further a high dielectric constant film or a high permittivity film (high-k film) may be annealed. In addition, in the above embodiments, the process gas is diluted by mixing thereto the diluent gas in two steps at the maximum. However, not limited thereto, the process gas may be diluted by mixing thereto the diluent gas in three steps or more. In such a modification, it goes without saying that a diluent gas duct, a surplus-gas discharge duct, a mixer, and so on, are additionally provided in accordance with the number of the dilution steps.

Further, in the above embodiments, there has been described the example in which an O₂ gas or a moisture (steam) is diluted and supplied. However, not limited to these gases, a diluted process gas of a low density may be generated by mixing a plurality of process gases and thereafter diluting the thus obtained mixed gas. Furthermore, the present invention can be naturally applied to the supply of all the gases, and is particularly effective when a slight amount of gas such as a reaction accelerator, a reaction inhibitor, an oxidizing agent, and a reducing agent such as H₂ are added.

Moreover, in the film deposition process shown in FIG. 14B, a film is deposited by a thermal CVD method, which is by way of example. Not limited thereto, the present invention may be applied to a film deposition method by an ALD (Atomic Layer Deposition) method, a sputtering method, and a vapor deposition method. In addition, not limited to a film deposition process and an annealing process, the present invention can be applied to all the other processes such as an oxidation and diffusion process, an ashing process, and a modification process. In addition, although a semiconductor wafer is taken by way of example as an object to be processed, the present invention is not limited thereto and can be applied to a glass substrate, an LCD substrate, a ceramic substrate, and so on.

1. A process-gas supply system configured to supply a process gas diluted with a diluent gas to a gas using system, the process-gas supply system comprising:
a process gas tank configured to store the process gas;
a diluent gas tank configured to store the diluent gas;
a main gas duct connecting the process gas tank and the gas using system;
a plurality of flow rate controllers disposed on the main gas duct;
a diluent gas duct connecting the diluent gas tank to the main gas duct, the diluent gas duct being connected to the main gas duct at a position on an immediately downstream side of one of the flow rate controllers disposed on the main gas duct other than the flow rate controller on the most downstream side;
a flow rate controller disposed on the diluent gas duct; and
a surplus-gas discharge duct through which a surplus diluted process gas is discharged from the main gas duct, the surplus-gas discharge duct being connected to the main gas duct at a position on an immediately upstream side of one of the flow rate controllers disposed on the main gas duct other than the flow rate controller on the most upstream side.

2. The process-gas supply system according to claim 1, wherein
a pure process gas or a process gas diluted with a diluent gas to a predetermined density is accommodated in the process gas tank.

3. The process-gas supply system according to claim 1, further comprising a reusable gas duct connecting the surplus-gas discharge duct and the diluent gas duct,
wherein the reusable gas duct is configured such that all the discharged surplus gas or a part thereof in the surplus-gas discharge duct can be reused as the diluent gas.

4. The process-gas supply system according to claim 3, wherein
the reusable gas duct is provided with a process-gas removal filter configured to absorb the process gas from the diluted process gas containing the diluent gas and the process gas, and
the process-gas removal filter is configured to remove the process gas from the diluted process gas flowing through the reusable gas duct, and to allow the diluent gas to pass therethrough.

5. The process-gas supply system according to claim 1, further comprising a reusable gas duct connecting the surplus-gas discharge duct and an exhaust system disposed on the gas using system,
wherein the reusable gas duct is configured such that all the discharged surplus gas or a part thereof in the surplus-gas discharged duct can be reused as a purge gas for a vacuum pump of the exhaust system.

6. The process-gas supply system according to claim 5, wherein
the reusable gas duct is provided with a process-gas removal filter configured to absorb the process gas from the diluted process gas containing the diluent gas and the process gas, and
the process-gas removal filter is configured to remove the process gas from the diluted process gas flowing through the reusable gas duct, and to allow the diluent gas to pass therethrough.

7. The process-gas supply system according to claim 1, further comprising:
a density measuring instrument configured to measure a density of the process gas, the density measuring instrument being disposed on the main gas duct at a position immediately before the gas using system, or on the gas using system; and
a feedback control device configured to feedback-control a flow rate controller based on a value detected by the density measuring instrument.

8. The process-gas supply system according to claim 7, wherein
the flow rate controller to be feedback-controlled by the feedback control device is the flow rate controller disposed on the main gas duct.

9. The process-gas supply system according to claim 7, wherein
the flow rate controller to be feedback-controlled by the feedback control device is the flow rate controller disposed on the diluent gas duct.

10. The process-gas supply system according to claim 1, further comprising a discarded-gas discharge duct connected to the main gas duct at a position on the downstream side of the flow rate controller on the most downstream side,
wherein the discarded-gas discharge duct is configured such that the process gas flowing therethrough bypasses the gas using system and is discarded.

11. The process-gas supply system according to claim 1, wherein
the surplus-gas discharge duct is provided with a check valve that is opened when a pressure of the process gas reaches or exceeds a predetermined pressure.

12. The process-gas supply system according to claim 11, wherein
the surplus-gas discharge duct is provided with a needle valve at a position on the upstream side of the check valve.

13. The process-gas supply system according to claim 1, further comprising:
a pressure gauge disposed on the main gas duct, the pressure gauge being configured to measure a gas pressure in the main gas duct;
a pressure regulating valve disposed on the surplus-gas discharge duct; and
a valve control device configured to control a valve opening degree of the pressure regulating valve based on a value measured by the pressure gauge.

14. The process-gas supply system according to claim 1, wherein
a part of the main gas duct, which part is located between a connection position to which the surplus-gas discharge duct is connected and a connection position to which the diluent gas duct is connected on the downstream side of the former connection point to which the surplus-gas discharge duct is connected, has a cross section smaller than those of other parts of the main gas duct, the other parts being located adjacent to the part on the upstream side and the downstream side.

15. The process-gas supply system according to claim 1, further comprising:
a zirconia-type density measuring instrument disposed on the main gas duct, the zirconia-type measuring instrument being configured to measure an oxygen density of a gas in the main gas duct; and
a feedback control part configured to feedback-control a flow rate controller based on a value detected by the zirconia-type density measuring instrument.

16. The process-gas supply system according to claim 15, further comprising a measuring-instrument bypass pipe provided with an opening and closing valve, the measuring-instrument bypass pipe being disposed on the main gas duct,
wherein the measuring-instrument bypass pipe is configured such that the process gas flowing therethrough bypasses the zirconia-type measuring instrument.

17. The process-gas supply system according to claim 1, wherein
the gas using system is a film deposition apparatus configured to deposit a film on a surface of an object to be processed, or an annealing apparatus configured to anneal an object to be processed on which a film has been formed.

18. The process-gas supply system according to claim 17, wherein
the film is any one of a CuMn film, a high dielectric constant film, an Mn film, and a film containing Mn.

19. The process-gas supply system according to claim 1, further comprising a mixer disposed on the main gas duct at a position to which the diluent gas duct is connected.

20. The process-gas supply system according to claim 1, wherein
the diluent gas is formed of one or more gases selected from the group consisting of an N₂ gas and a rare gas.

21. The process-gas supply system according to claim 1, wherein
the process gas is an O₂ gas.

22. A process-gas supply system configured to supply a process gas diluted with a diluent gas to a gas using system, the process-gas supply system comprising:
a liquid material tank configured to store a liquid material of the process gas;
a diluent gas tank configured to store the diluent gas;
a main gas duct connecting the liquid material tank and the gas using system;
a flow rate controller disposed on the main gas duct; and
a diluent gas duct connecting the diluent gas tank to the main gas duct, the diluent gas duct being connected to the main gas duct at a position on a downstream side of the flow rate controller disposed on the main gas duct.

23. The process-gas supply system according to claim 22, wherein
the liquid material tank is configured such that a process gas, which is generated by evaporating the liquid material in the liquid material tank, outflows to the main gas duct.

24. The process-gas supply system according to claim 22, further comprising:
a plurality of flow rate controllers disposed on the main gas duct; and
a surplus-gas discharge duct through which a surplus diluted process gas is discharged from the main gas duct, the surplus-gas discharge duct being connected to the main gas duct at a position on an immediately upstream side of one of the flow rate controllers disposed on the main gas duct other than the flow rate controller on the most upstream side,
wherein the diluent gas duct is connected to the main gas duct at a position on an immediately downstream side of one of the flow rate controllers disposed on the main gas duct other than the flow rate controller on the most downstream side.

25. The process-gas supply system according to claim 22, further comprising a pressure regulating valve mechanism disposed on the main gas duct at a position on the immediately
a surplus-gas discharge duct through which a surplus diluted process gas is discharged from the main gas duct, the surplus-gas discharge duct being connected to the main gas duct at a position on an immediately upstream side of one of the flow rate controllers disposed on the main gas duct other than the flow rate controller on the most upstream side;
wherein the diluent gas duct is connected to the main gas duct at a position on an immediately downstream side of one of the flow rate controllers disposed on the main gas duct other than the flow rate controller on the most downstream side.

30. The process-gas supply system according to claim 27, further comprising a pressure regulating valve mechanism disposed on the main gas duct at a position on an immediately downstream side of the liquid material tank.

31. The process-gas supply system according to claim 27, wherein
the process gas is a steam.

32. A process-gas supply system configured to supply a process gas diluted with a diluent gas to a gas using system, the process-gas supply system comprising:
a process-gas forming part configured to form the process gas;
a diluent gas tank configured to store the diluent gas;
a main gas duct connecting the process-gas forming part and the gas using system;
a flow rate controller disposed on the main gas duct;
a diluent gas duct connecting the diluent gas tank to the main gas duct, the diluent gas duct being connected to the main gas duct at a position on an upstream side of the flow rate controller disposed on the main gas duct;
a flow rate controller disposed on the diluent gas duct; and
a surplus-gas discharge duct through which a surplus diluted process gas is discharged from the main gas duct, the surplus-gas discharge duct being connected to the main gas duct at a position on the immediately upstream side of the flow rate controller disposed on the main gas duct.

33. The process-gas supply system according to claim 32, wherein
the process-gas forming part includes:
a material-gas supply system configured to supply a plurality of material gases for forming the process gas, with flow rates of the material gases being independently controlled; and
a reaction part configured to react the plurality of material gases from the material-gas supply system so as to form the process gas.

34. The process-gas supply system according to claim 32, wherein
the plurality of material gases are an H₂ gas and an O₂ gas, and the process gas is a steam.

35. The process-gas supply system according to claim 32, further comprising:
a density measuring instrument configured to measure a density of the process gas, the density measuring instrument being disposed on the main gas duct at a position immediately before the gas using system, or on the gas using system; and
a feedback control device configured to feedback-control a flow rate controller based on a value detected by the density measuring instrument.

36. The process-gas supply system according to claim 35, wherein
the flow rate controller to be feedback-controlled by the feedback control device is the flow rate controller disposed on the main gas duct, or a flow rate controller disposed on the process-gas forming part.

37. The process-gas supply system according to claim 35, wherein
the flow rate controller to be feedback-controlled by the feedback control device is the flow rate controller disposed on the diluent gas duct.

38. A processing system configured to subject an object to be processed to a predetermined process, the processing apparatus comprising:
a processing container capable of accommodating one or more objects to be processed;
a gas introduction member configured to introduce a gas into the processing container; and
the process-gas supply system according to claim 1, connected to the gas introduction member for supplying a process gas diluted with a diluent gas into the processing container.

39. The processing system according to claim 38, further comprising an exhaust system configured to discharge an atmosphere in the processing container,
wherein the exhaust system includes: a main exhaust duct provided with an opening and closing valve and a vacuum pump; and a bypass exhaust duct provided with an opening and closing valve, for atmospheric pressure process, the bypass exhaust duct being connected to the main exhaust duct such that the bypass exhaust duct bypasses the vacuum pump.
